(19) United States
(12) Patent Application Publication
(10) Pub. No.: US 2011/0233604 A1
(43) Pub. Date: Sep. 29, 2011

(54) ORGANIC ELECTROLUMINESCENCE DEVICE

(76) Inventor: Takeshi IKEDA, Kanazawa-shi (JP)

(21) Appl. No.: 13/047,240

(22) Filed: Mar. 14, 2011

(30) Foreign Application Priority Data
Mar. 24, 2010 (JP) 2010-068939

(51) Int. Cl. H01L 51/52

(52) U.S. Cl. 257/103; 257/E51.018

(57) ABSTRACT

According to one embodiment, an organic electroluminescence device including an anode, a cathode, an emitting layer positioned therebetween and including a first host material and a first dopant, and an organic layer in contact with the emitting layer between the cathode and the emitting layer and including a second host material and a second dopant. The first host material has a hole-transporting property. The first dopant has a blue-fluorescent property and fluorescence thereof exhibits the maximum intensity at a first wavelength. The second host material has an electron-transporting property. The second host material has an ionization energy higher than an ionization energy of the first host material. The second dopant has an ionization energy lower than the ionization energy of the first host material. The second dopant has fluorescent and/or phosphorescent properties and luminescence thereof exhibits the maximum intensity at a second wavelength shorter than the first wavelength.

### CROSS-REFERENCE TO RELATED APPLICATIONS

This application is based upon and claims the benefit of priority from Japanese Patent Application No. 2010-068939, filed Mar. 24, 2010; the entire contents of which are incorporated herein by reference.

### FIELD

Embodiments described herein relate generally to an organic electroluminescence (hereinafter, referred to as EL) device.

### BACKGROUND

One-fourth of excitons generated by injecting charges into an organic EL element are singlet excitons, while three-fourth of the excitons thus generated are triplet excitons. Therefore, for an organic EL element utilizing only fluorescence, which is caused when transition of an electron from the singlet excited state to the ground state occurs, it had been believed that the theoretically achievable inner quantum efficiency was 25% at the maximum.

An organic EL element utilizing phosphorescence, which is caused when transition of an electron from the triplet excited state to the ground state occurs, can theoretically achieve a higher inner quantum efficiency than the organic EL element utilizing only fluorescence. Taking the intersystem crossing from the singlet excited state to the triplet excited state into consideration, the theoretically achievable inner quantum efficiency is 100% at the maximum.

However, in general, phosphorescent materials are complexes of heavy atoms. In addition, in order to effectively use the energy of triplet excitons in an organic EL element utilizing phosphorescence, a material whose excitation energy is high need to be used as a host material included in the emitting layer and such a material also need to be used as a material of a layer adjacent to the emitting layer. For these reasons, organic EL elements utilizing phosphorescence have a drawback of a short luminance-half-life.

Meanwhile, studies has been made in recent years to utilize singlet excitons that are generated when triplet-triplet annihilation of triplet excitons occurs for light emission in an organic EL element using fluorescence. Utilization of this theoretically allows 40% of inner quantum efficiency at the maximum.

### BRIEF DESCRIPTION OF THE DRAWINGS

FIG. 1 is a sectional view schematically showing an example of an organic EL element that can be used in an organic EL device according to an embodiment;

FIG. 2 is an example of an energy level diagram of the organic EL element shown in FIG. 1;

FIG. 3 is a sectional view schematically showing another example of an organic EL element that can be used in an organic EL device according to an embodiment;

FIG. 4 is an example of an energy level diagram of the organic EL element shown in FIG. 3;

FIG. 5 is a plan view schematically showing an organic EL device according to an embodiment;

FIG. 6 is a sectional view schematically showing an example of a structure that can be employed in the organic EL device shown in FIG. 5;

FIG. 7 is a sectional view schematically showing an organic EL device according to a modification;

FIGS. 8 to 36 are sectional views schematically showing organic EL devices according to other modifications;

FIG. 37 is a graph showing absorption spectra of the first dopant and the first host material used in elements A and B and emission spectra of the second dopant and the second host material used in the elements A and B; and

FIG. 38 is a graph showing transient responses obtained for the elements A and B.

### DETAILED DESCRIPTION

In general, according to one embodiment, there is provided an organic electroluminescence device comprising an anode, a cathode, an emitting layer positioned between the anode and the cathode and including a first host material and a first dopant, the first host material having a hole-transporting property, the first dopant having a blue-fluorescent property, fluorescent of the first dopant exhibiting the maximum intensity at a first wavelength, and an organic layer in contact with the emitting layer between the cathode and the emitting layer and including a second host material and a second dopant, the second host material having an electron-transporting property, the second dopant having at least one of fluorescent and phosphorescent properties, the second host material having an ionization energy higher than an ionization energy of the first host material, the second dopant having an ionization energy lower than the ionization energy of the first host material, luminescence of the second dopant exhibiting the maximum intensity at a second wavelength shorter than the first wavelength.

According to another embodiment, there is provided an organic electroluminescence device comprising first to third anodes, a cathode facing the first to third anodes, a first emitting layer positioned between the first anode and the cathode and including a host material and a dopant having a red-fluorescent property, a second emitting layer positioned between the second anode and the cathode and the cathode and including a host material and a dopant having a green-fluorescent property, a third emitting layer positioned between the third anode and the cathode and including a first host material having an electron-transporting property and a first dopant having a blue-fluorescent property, fluorescent of the first dopant exhibiting the maximum intensity at a first wavelength, and an organic layer in contact with the third emitting layer between the third anode and the third emitting layer and including a second host material and a second dopant, the second host material having a hole-transporting property, the second dopant having at least one of fluorescent and phosphorescent properties, the second host material having an electron affinity lower than an electron affinity energy of the first host material, the second dopant having an electron affinity higher than the electron affinity of the first host material, luminescence of the second dopant exhibiting the maximum intensity at a second wavelength shorter than the first wavelength.

According to another embodiment, there is provided an organic electroluminescence device comprising an anode, a cathode, an emitting layer positioned between the anode and the cathode and including a first host material and a first dopant, the first host material having an electron-transporting property, the first dopant having a blue-fluorescent property, fluorescent of the first dopant exhibiting the maximum intensity at a first wavelength, and an organic layer in contact with the emitting layer between the anode and the emitting layer and including a second host material and a second dopant, the second host material having a hole-transporting property, the second dopant having at least one of fluorescent and phosphorescent properties, the second host material having an electron affinity lower than an electron affinity energy of the first host material, the second dopant having an electron affinity higher than the electron affinity of the first host material, luminescence of the second dopant exhibiting the maximum intensity at a second wavelength shorter than the first wavelength.

According to still another embodiment, there is provided an organic electroluminescence device comprising first to third anodes, a cathode facing the first to third anodes, a first emitting layer positioned between the first anode and the cathode and including a host material and a dopant having a red-fluorescent property, a second emitting layer positioned between the second anode and the cathode and the cathode and including a host material and a dopant having a green-fluorescent property, a third emitting layer positioned between the third anode and the cathode and including a first host material having an electron-transporting property and a first dopant having a blue-fluorescent property, fluorescent of the first dopant exhibiting the maximum intensity at a first wavelength, and an organic layer in contact with the third emitting layer between the third anode and the third emitting layer and including a second host material and a second dopant, the second host material having a hole-transporting property, the second dopant having at least one of fluorescent and phosphorescent properties, the second host material having an electron affinity lower than an electron affinity energy of the first host material, the second dopant having an electron affinity higher than the electron affinity of the first host material, luminescence of the second dopant exhibiting the maximum intensity at a second wavelength shorter than the first wavelength.

Embodiments will be described below in detail with reference to the drawings. In the drawings, the same reference characters denote components having the same or similar functions and duplicates descriptions will be omitted.

FIG. 1 is a sectional view schematically showing an example of an organic EL element that can be used in an organic EL device according to an embodiment.

The organic EL element OLED shown in FIG. 1 has a multilayered structure that includes an anode AND, a hole injection layer HIL, a hole-transporting layer HTL, an emitting layer EML, an organic layer CEL, an electron-transporting layer ETL, an electron injection layer EIL and a cathode CTD.

The anode AND is made of, for example, metals, alloys, conductive metal compounds or combinations thereof. The anode AND may have a single-layer structure or multilayer structure. For example, indium tin oxide (hereinafter referred to as ITO) layer is used as the anode AND.

The cathode CTD is made of, for example, metals, alloys, conductive metal compounds or combinations thereof. The cathode CTD may have a single-layer structure or multilayer structure. Typically, the cathode CTD has a work function lower than the work function of the anode AND. For example, an aluminum layer is used as the cathode CTD.

The emitting layer EML is interposed between the anode AND and the cathode CTD. The emitting layer is a layer made of an organic material, for example, a mixture including a first host material and a first dopant.

The first host material is typically a component of the emitting layer EML having the maximum mass fraction. Typically, the mass fraction of the first host material in the emitting layer EML is greater than 50%.

The first host material has a hole-transporting property. Typically, the hole mobility of the first host material is higher than the electron mobility of the first host material. As such a material, for example, 1,1′-(dimethoxy-1,4′-phenylene)dipyrene (hereinafter referred to as DOPPP) can be used.

The first host material has at least one of fluorescent and phosphorescent properties, typically, a fluorescent property. The first host material is selected such that its emission spectrum overlaps the absorption spectrum of the first dopant at least partially.

The first dopant is, for example, a dopant having a fluorescent property. The first dopant may be a dopant having fluorescent and phosphorescent properties. That is, the first dopant may be a mixture including a dopant having a fluorescent property and a dopant having a phosphorescent property. As the first dopant, for example, 4,4′-bis[4-(diphenylamino)styryl]biphenyl (hereinafter referred to as BDAVBi) can be used. Here, as an example, the first dopant is assumed to have a blue-fluorescent property.

The hole-transporting layer HTL is interposed between the anode AND and the emitting layer EML. The hole-transporting layer HTL is made of an organic material and typically has an ionization energy between the work function of the anode AND and the ionization energy of the emitting layer EML. As the material of the hole-transporting layer HTL, for example, bis-naphthyl-phenylamino-biphenyl (hereinafter referred to as α-NPD) can be used. The hole-transporting layer HTL can be omitted.

The hole injection layer HIL is interposed between the anode AND and the hole-transporting layer HTL. The hole injection layer HIL is made of an organic material, an inorganic material or an organometallic compound and typically has an ionization energy between the work function of the anode AND and the ionization potential of the hole-transporting layer HTL. As the material of the hole injection layer HIL, for example, amorphous carbon or copper phthalocyanine (hereinafter referred to as CuPc) can be used. The hole injection layer can be omitted.

The electron-transporting layer ETL is interposed between the emitting layer EML and the cathode CTD. The electron-transporting layer ETL is made of, for example, an organic material and typically has an electron affinity between the electron affinity of the emitting layer EML and the work function of the cathode CTD. As the material of the electron-transporting layer ETL, for example, tris(8-quinolilato)aluminum (hereinafter referred to as Alq₃) or 2-phenyl-5-(4-biphenyl)-1,3,4-oxadiazole (hereinafter referred to as OXD) can be used.

The electron injection layer EIL is interposed between the electron-transporting layer ETL and the cathode CTD. The electron injection layer EIL is made of, for example, an organic material, an inorganic material or an organometallic compound and typically has an electron affinity between the electron affinity of the electron-transporting layer ETL and the work function of the cathode CTD. As the material of the electron injection layer EIL, for example, lithium fluoride can be used. The electron injection layer EIL can be omitted.

The organic layer (hereinafter referred to as charge-escape layer) CEL is in contact with the emitting layer EML between the emitting layer EML and the electron-transporting layer ETL. The charge-escape layer CEL includes a second host material and a second dopant.

The second host material is, for example, a component of the charge-escape layer CEL having the maximum mass fraction. Typically, the mass fraction of the second host material in the charge-escape layer CEL is greater than 50%.

The second host material has an electron-transporting property. Typically, the electron mobility of the second host material is higher than the hole mobility of the second host material. As such a material, for example, bathocuproin (hereinafter referred to as BCP) can be used.

The second host material has an ionization potential higher than the ionization potential of the first host material. The second host material has, for example, an electron affinity lower than the electron affinity of the first host material.

The second host material may have at least one of fluorescent and phosphorescent properties, for example, a fluorescent property. In this case, the second host material can be selected, for example, such that its emission spectrum at least partially overlaps the absorption spectrum of the second dopant, the absorption spectrum of the first host material, the absorption spectrum of the first dopant, or two or more of them.

The second dopant may have a fluorescent or phosphorescent property. Alternatively, the second dopant may have fluorescent and phosphorescent properties. That is, the second dopant may be a mixture including a dopant having a fluorescent property and a dopant having a phosphorescent property.

The second dopant has an ionization energy lower than the ionization energy of the first host material. Typically, the wavelength at which the second dopant emits light at the maximum intensity is shorter than the wavelength at which the first dopant emits fluorescent light at the maximum intensity. In this case, the light emitted by the second dopant can be utilized for exciting the first dopant. For example, in the case where the emission spectrum of the second dopant at least partially overlaps the absorption spectrum of the first dopant, the fluorescent and/or phosphorescent light emitted by the second dopant can be directly utilized as an excitation light for the first dopant.

As the second dopant, for example, 1,3-bis(9,9′-spirobifluorene-2-yl)benzene (hereinafter referred to as BSB) can be used. Here, as an example, the second dopant is assumed to have a fluorescent property and emits purple visual rays or ultraviolet rays.

When employing the above-described structure, it is possible to effectively utilize the singlet exciton generated by the triplet-triplet annihilation. This will be described below.

The triplet-triplet annihilation is a phenomenon in which triplet excitons collide with each other to generate a singlet exciton as shown in the following equation.

4(³M*+³M*)→¹M*+3³M*+4M

In the above equation, the symbol “³M*” indicates a triplet exciton, the symbol “¹M*” indicates a singlet exciton, and the symbol “M” indicates a pair of an electron and a hole dissociate from each other.

In the case where the singlet excitons generated by the collision of the triplet excitons in addition to the singlet excitons generated by injection of carriers into the emission layer can be utilized for fluorescence in the emission layer, a higher inner quantum efficiency can be achieved as compared with the case where only the singlet excitons generated by injection of carriers into the emission layer are utilized for fluorescence in the emission layer. A high inner quantum efficiency is advantageous in achieving a higher luminance, a reduced power consumption, and a longer life-time.

Meanwhile, an organic EL element generally employs a structure in which the emitting layer is less prone to release charges injected therein into adjacent layers in order to increase the inner quantum efficiency. For example, in the case where the hole mobility is higher than the electron mobility in the emitting layer and the hole injection efficiency for the emitting layer is higher than the electron injection efficiency for the emitting layer, employed is a structure in which the ionization energy of the electron-transporting layer is higher than the ionization energy of the emitting layer in order to suppress that the holes injected into the emitting layer is released into the electron-transporting layer without utilized for generation of excitons.

In the case of employing this design, excitons are mainly generated in the region of the emitting layer near the interface between the emitting layer and the electron-transporting layer. However, charges, holes in this case, are also present in this region. When excitons collide with charges, nonradiative transition from the excited state to the ground state occurs. Thus, triplet excitons cannot exist in the emitting layer at a high density. For this reason, a ratio of the singlet excitons generated by collision of the triplet excitons with respect to the charges injected into the emitting layer is small.

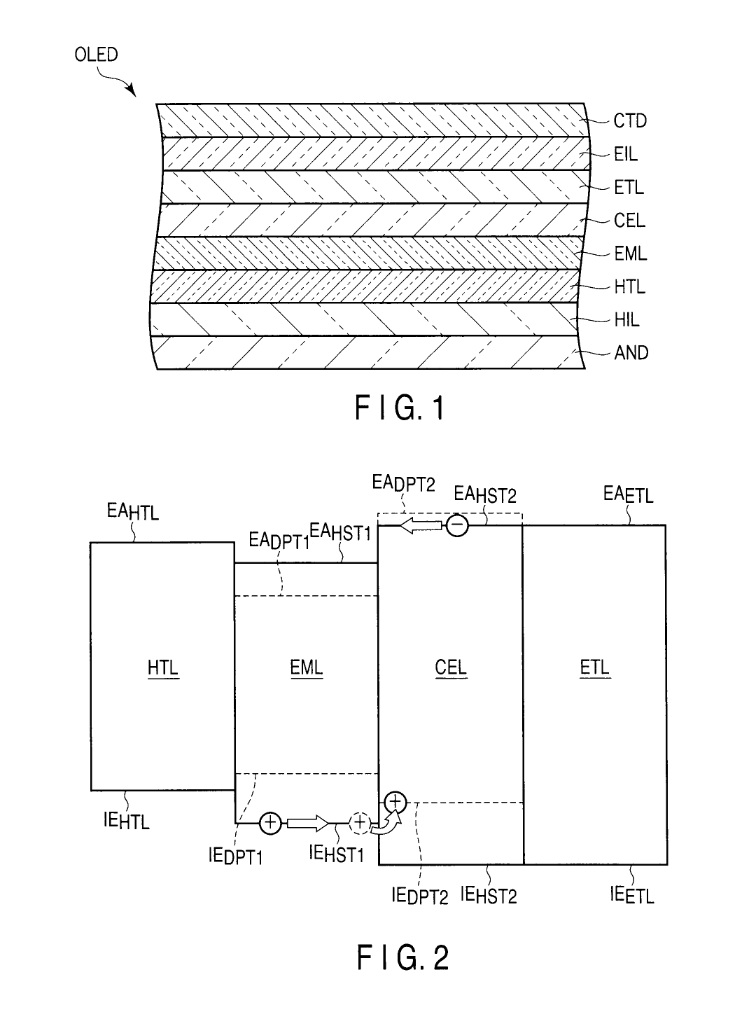

FIG. 2 is an example of an energy level diagram of the organic EL element shown in FIG. 1.

In FIG. 2, the reference symbols “EA_{HTL}” and “IE_{HTL}” indicate the electron affinity and the ionization energy of the hole-transporting layer HTL, respectively. The reference symbols “EA_{ETL}” and “IE_{ETL}” indicate the electron affinity and the ionization energy of the electron-transporting layer ETL, respectively. The reference symbols “EA_{HST1}” and “IE_{HST1}” indicate the electron affinity and the ionization energy of the first host material that the emitting layer EML contains, respectively. The reference symbols “EA_{DPT1}” and “IE_{DPT1}” indicate the electron affinity and the ionization energy of the first dopant that the emitting layer EML contains, respectively. The reference symbolsFA “EA_{HST2}” and “IE_{HST2}” indicate the electron affinity and the ionization energy of the second host material that the charge-escape layer CEL contains, respectively. The electron affinity and the ionization energy of the second dopant that the charge-escape layer CEL contains, respectively.

In FIG. 2, the ionization energy IE_{DPT1} of the first dopant included in the emitting layer EML is lower than the ionization energy IE_{HST1} of the first host material included in the emitting layer EML. The electron affinity EA_{DPT1} of the first dopant included in the emitting layer EML is lower than the electron affinity EA_{HST1} of the first host material included in the emitting layer EML.

The ionization energy IE_{HTL} of the hole-transporting layer HTL is lower than the ionization energy IE_{HST1} of the first host material included in the emitting layer EML and higher than the ionization energy IE_{DPT1} of the first dopant included in the emitting layer EML. The electron affinity EA_{HTL} of the hole-transporting layer HTL is lower than the electron affinity EA_{HST1} of the first host material included in the emitting layer EML and the electron affinity EA_{DPT1} of the first dopant included in the emitting layer EML.

The ionization energy IE_{ETL} of the electron-transporting layer ETL is higher than the ionization energy IE_{HST1} of the first host material included in the emitting layer EML and the ionization energy IE_{DPT1} of the first dopant included in the emitting layer EML. The electron affinity EA_{ETL} of the electron-transporting layer ETL is lower than the electron affinity EA_{HST1} of the first host material included in the emitting layer EML and the electron affinity EA_{DPT1} of the first dopant included in the emitting layer EML.

The ionization energy IE_{HST2} of the second host material included in the charge-escape layer CEL is higher than the ionization energy IE_{HST1} of the first host material included in the emitting layer EML and the ionization energy IE_{DPT1} of the first dopant included in the emitting layer EML and almost equal to the ionization energy IE_{ETL} of the electron-transporting layer ETL. The electron affinity EA_{HST2} of the second host material is lower than the electron affinity EA_{HST1} of the first host material included in the emitting layer EML and the electron affinity EA_{DPT1} of the first dopant included in the emitting layer EML and almost equal to the electron affinity EA_{ETL} of the electron-transporting layer ETL.

The ionization energy IE_{DPT2} of the second dopant included in the charge-escape layer CEL is lower than the ionization energy IE_{HST2} of the second host material included in the charge-escape layer CEL, lower than the ionization energy IE_{HST1} of the first host material included in the emitting layer EML, higher than the ionization energy IE_{DPT1} of the first dopant included in the emitting layer EML, and lower than the ionization energy IE_{ETL} of the electron-transporting layer ETL. The electron affinity EA_{DPT2} of the second dopant is slightly lower than the electron affinity EA_{HST2} of the second host material included in the charge-escape layer CEL, lower than the electron affinity EA_{HST1} of the first host material included in the emitting layer and the electron affinity EA_{DPT1} of the first dopant included in the emitting layer EML, and slightly lower than the electron affinity EA_{ETL} of the electron-transporting layer ETL.

As described above, in FIG. 2, the ionization energy IE_{HST2} of the second host material included in the charge-escape layer CEL is higher than the ionization energy IE_{HST1} of the first host material included in the emitting layer EML. Thus, in the case where the hole mobility is higher than the electron mobility in the emitting layer EML and the hole injection efficiency for the emitting layer EML is higher than the electron injection efficiency for the emitting layer EML, excitons can be generated at a high density in the region of the emitting layer EML near the interface between the emitting layer EML and the charge-escape layer CEL.

In FIG. 2, the ionization energy IE_{DPT2} of the second dopant included in the charge-escape layer CEL is lower than the ionization energy IE_{DPT1} of the first dopant included in the emitting layer EML. Thus, holes can be released from the emitting layer EML into the charge-escape layer CEL, which makes it possible to prevent the density of holes in the above region becomes excessively high.

As above, when the design shown in FIG. 2 is employed, it is possible to prevent the density of charges becomes excessively high in a specific region of the emitting layer EML and to make triplet excitons exist at a high density in this region. Thus, a ratio of singlet excitons generated by collision of triplet excitons with respect to charges injected into the emitting layer EML can be increased. Therefore, triplet-triplet annihilation can be effectively utilized for increasing inner quantum efficiency.

In the case of employing the design shown in FIG. 2, the holes released from the emitting layer EML into the charge-escape layer CEL and electrons injected from the electron-transporting layer ETL into the charge-escape layer CEL can generate excitons. The energy generated when transition of the excitons from the excited state to the ground state occurs can be directly or indirectly utilized for exciting the first dopant. Utilizing this energy for exciting the first dopant can further increase the inner quantum efficiency.

As above, the organic EL element OLED described with reference to FIGS. 1 and 2 employs a design that allows holes to be accumulated in the region of the emitting layer EML adjacent to the charge-escape layer CEL, allows excitons to be generated in this region at a high density, and allows excessive holes in this region to readily move into the escape layer CEL. Instead, the organic EL element OLED may employ a structure that allows electrons to be accumulated in the region of the emitting layer EML adjacent to the charge-escape layer CEL, allows excitons to be generated in this region at a high density, and allows excessive electrons in this region to readily move into the escape layer CEL as will be described below.

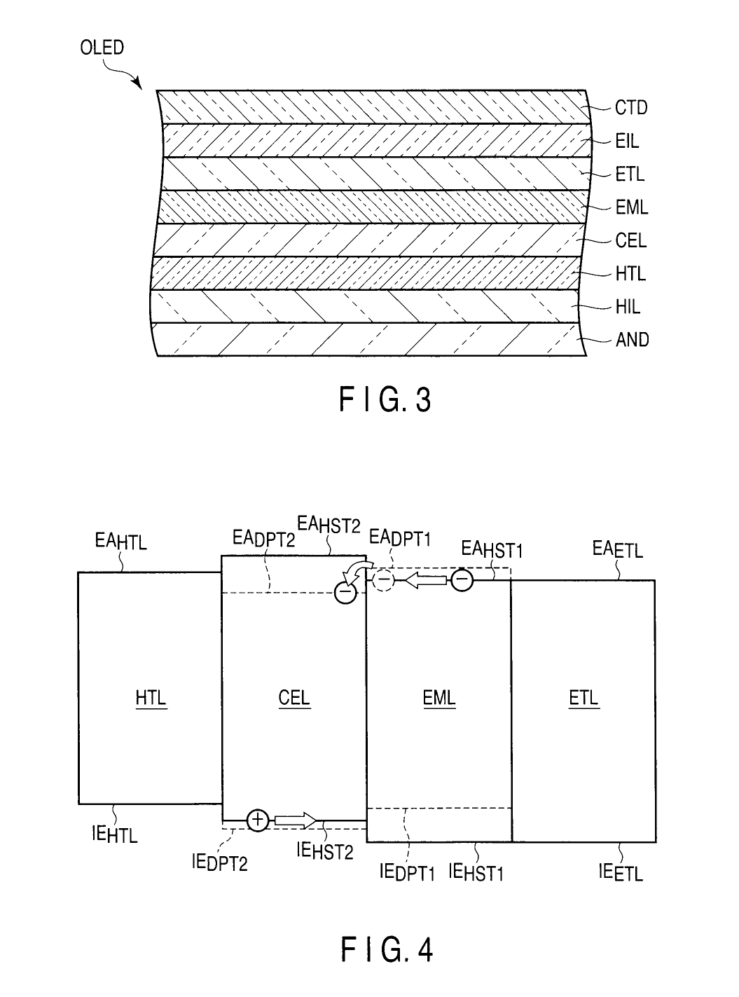

FIG. 3 is a sectional view schematically showing another example of an organic EL element that can be used in an organic EL device according to an embodiment.

The organic EL element OLED shown in FIG. 3 is the same as the organic EL element OLED described with reference to FIG. 1 except for the following.

The first host material is typically a component of the emitting layer EML having the maximum mass fraction. Typically, the mass fraction of the first host material in the emitting layer EML is greater than 50%.

The first host material has an electron-transporting property. Typically, the electron mobility of the first host material is higher than the hole mobility of the first host material. As such a material, for example, 9,10-di(2-naphthyl)anthracene (hereinafter referred to as ADN) can be used.

The first host material has at least one of fluorescent and phosphorescent properties, typically, a fluorescent property. The first host material is selected such that its emission spectrum overlaps the absorption spectrum of the first dopant at least partially.

The first dopant is, for example, a dopant having a fluorescent property. The first dopant may be a dopant having fluorescent and phosphorescent properties. That is, the first dopant may be a mixture including a dopant having a fluorescent property and a dopant having a phosphorescent property. As the first dopant, for example, BDAVBi can be used. Here, as an example, the first dopant is assumed to have a blue-fluorescent property.

The charge-escape layer CEL is in contact with the emitting layer EML between the emitting layer EML and the hole-transporting layer HTL.

The second host material included in the charge-escape layer CEL is, for example, a component of the charge-escape layer CEL having the maximum mass fraction. Typically, the mass fraction of the second host material in the charge-escape layer CEL is greater than 50%.

The second host material has a hole-transporting property. Typically, the hole mobility of the second host material is higher than the electron mobility of the second host material. As such a material, for example, 4,4′-bis[N,N′-(3tolyl)amino]-3,3′-dimethylbiphenyl (hereinafter referred to as HMTPD) can be used.

The second host material has an electron affinity lower than the electron affinity of the first host material. The second host material has, for example, an ionization energy lower than the ionization energy of the first host material.

The second host material may have at least one of fluorescent and phosphorescent properties, for example, a fluorescent property. In this case, the second host material can be selected, for example, such that its emission spectrum at least partially overlaps the absorption spectrum of the second dopant, the absorption spectrum of the first host material, the absorption spectrum of the first dopant, or two or more of them.

The second dopant may have a fluorescent or phosphorescent property. Alternatively, the second dopant may have fluorescent and phosphorescent properties. That is, the second dopant may be a mixture including a dopant having a fluorescent property and a dopant having a phosphorescent property.

The second dopant has an electron affinity higher than the electron affinity of the first host material. Typically, the wavelength at which the second dopant emits light at the maximum intensity is shorter than the wavelength at which the first dopant emits fluorescent light at the maximum intensity. In this case, the light emitted by the second dopant can be utilized for exciting the first dopant. For example, in the case where the emission spectrum of the second dopant at least partially overlaps the absorption spectrum of the first dopant, the fluorescent and/or phosphorescent light emitted by the second dopant can be directly utilized as an excitation light for the first dopant.

As the second dopant, for example, 2,3,6,7,10,11-hexatryltriphenylene (hereinafter referred to as HTP) can be used. Here, as an example, the second dopant is assumed to have a fluorescent property and emits purple visual rays or ultraviolet rays.

When employing the above-described structure, it is possible to effectively utilize the singlet exciton generated by the triplet-triplet annihilation. This will be described below.

As described above, an organic EL element generally employs a structure in which the emitting layer is less prone to release charges injected therein into adjacent layers in order to increase the inner quantum efficiency. For example, in the case where the electron mobility is higher than the hole mobility in the emitting layer and the electron injection efficiency for the emitting layer is higher than the hole injection efficiency for the emitting layer, employed is a structure in which the electron affinity of the hole-transporting layer is lower than the electron affinity of the emitting layer in order to suppress that the electrons injected into the emitting layer is released into the hole-transporting layer without utilized for generation of excitons.

In the case of employing this design, excitons are mainly generated in the region of the emitting layer near the interface between the emitting layer and the hole-transporting layer. However, charges, electrons in this case, are also present in this region. When excitons collide with charges, nonradiative transition from the excited state to the ground state occurs. Thus, triplet excitons cannot exist in the emitting layer at a high density. For this reason, a ratio of the singlet excitons generated by collision of the triplet excitons with respect to the charges injected into the emitting layer is small.

FIG. 4 is an example of an energy level diagram of the organic EL element shown in FIG. 3.

In FIG. 4, the ionization energy IE_{DPT1} of the first dopant included in the emitting layer EML is lower than the ionization energy IE_{HST1} of the first host material included in the emitting layer EML. The electron affinity EA_{DPT1} of the first dopant included in the emitting layer EML is slightly lower than the electron affinity EA_{HST1} of the first host material included in the emitting layer.

The ionization energy IE_{HTL} of the hole-transporting layer HTL is lower than the ionization energy IE_{HST1} of the first host material included in the emitting layer EML and almost equal to the ionization energy IE_{DPT1} of the first dopant included in the emitting layer EML. The electron affinity EA_{HTL} of the hole-transporting layer HTL is almost equal to the electron affinity EA_{HST1} of the first host material included in the emitting layer EML and the electron affinity EA_{DPT1} of the first dopant included in the emitting layer EML.

The ionization energy IE_{ETL} of the electron-transporting layer ETL is almost equal to the ionization energy IE_{HST1} of the first host material included in the emitting layer EML and higher than the ionization energy IE_{DPT1} of the first dopant included in the emitting layer EML. The electron affinity EA_{ETL} of the electron-transporting layer ETL is almost equal to the electron affinity EA_{HST1} of the first host material included in the emitting layer EML and slightly higher than the electron affinity EA_{DPT1} of the first dopant included in the emitting layer EML.

The ionization energy IE_{HST2} of the second host material included in the charge-escape layer CEL is lower than the ionization energy IE_{HST1} of the first host material included in the emitting layer EML, higher than the ionization energy IE_{DPT1} of the first dopant included in the emitting layer EML, and higher than the ionization energy IE_{ETL} of the electron-transporting layer ETL. The electron affinity EA_{HST2} of the second host material is lower than the electron affinity EA_{HST1} of the first host material included in the emitting layer and lower than the electron affinity EA_{ETL} of the electron-transporting layer ETL.

The ionization energy IE_{DPT2} of the second dopant included in the charge-escape layer CEL is slightly higher than the ionization energy IE_{HST2} of the second host material included in the charge-escape layer CEL, lower than the ionization energy IE_{HST1} of the first host material included in the emitting layer EML, higher than the ionization energy IE_{DPT1} of the first dopant included in the emitting layer EML, and higher than the ionization energy IE_{ETL} of the electron-transporting layer ETL. The electron affinity EA_{DPT2} of the second dopant is higher than the electron affinity EA_{HST2} of the second host material included in the charge-escape layer CEL, higher than the electron affinity EA_{HST1} of the first host material included in the emitting layer EML and the electron affinity EA_{DPT1} of the first dopant included in the emitting layer EML, and higher than the electron affinity EA_{HTL} of the hole-transporting layer HTL.

As described above, in FIG. 4, the electron affinity EA_{HST2} of the second host material included in the charge-escape layer CEL is lower than the electron affinity EA_{HST1} of the first host material included in the emitting layer EML. Thus, for example, in the case where the electron mobility is higher than the hole mobility in the emitting layer EML and the electron injection efficiency for the emitting layer EML is higher than the hole injection efficiency for the emitting layer EML, excitons can be generated at a high density in the region of the emitting layer EML near the interface between the emitting layer EML and the charge-escape layer CEL.

In FIG. 4, the electron affinity EA_{DPT2} of the second dopant included in the charge-escape layer CEL is higher than the electron affinity EA_{DPT1} of the first dopant included in the emitting layer EML. Thus, electrons can be released from the emitting layer EML into the charge-escape layer CEL, which makes it possible to prevent the density of electrons in the above region becomes excessively high.

As above, when the design shown in FIG. 4 is employed, it is possible to prevent the density of charges becomes excessively high in a specific region of the emitting layer EML and to make triplet excitons exist at a high density in this region. Thus, a ratio of singlet excitons generated by collision of triplet excitons with respect to charges injected into the emitting layer EML can be increased. Therefore, triplet-triplet annihilation can be effectively utilized for increasing inner quantum efficiency.

In the case of employing the design shown in FIG. 4, the electrons released from the emitting layer EML into the charge-escape layer CEL and holes injected from the hole-transporting layer HTL into the charge-escape layer CEL can generate excitons. The energy generated when transition of the excitons from the excited state to the ground state occurs can be directly or indirectly utilized for exciting the first dopant. Utilizing this energy for exciting the first dopant can further increase the inner quantum efficiency.

Various modifications can be made to the organic EL elements OLED described with reference to FIGS. 1 to 4.

For example, in the organic EL element OLED described with reference to FIGS. 1 and 2, the ionization energy IE_{DPT1} of the first dopant may be equal to or higher than the ionization energy IE_{HST1} of the first dopant included in the emitting layer EML. The electron affinity EA_{DPT1} of the first dopant included in the emitting layer EML may be equal to or higher than the electron affinity EA_{DPT1} of the first host material. The electron affinity EA_{DPT1} of the first dopant included in the emitting layer EML may be between the electron affinity EA_{DPT2} of the second dopant and the electron affinity EA_{DPT2} of the second host material included in the charge-escape layer CEL, may be higher or lower than them, or may be equal to one of them. The ionization energy IE_{DPT1} of the first dopant may be between the ionization energy IE_{DPT2} of the second dopant and the ionization energy IE_{HST2} of the second host material included in the charge-escape layer CEL, may be higher than them, or may be equal to one of them. The ionization energy IE_{HST1} of the first host material may be between the ionization energy IE_{DPT2} of the second dopant and the ionization energy IE_{HST2} of the second host material included in the charge-escape layer CEL, may be lower than them, or may be equal to one of them.

In the organic EL elements OLED described with reference to FIGS. 1 and 2, the ionization energy IE_{HTL} may be between the ionization energy IE_{DPT1} of the first dopant and the ionization energy IE_{HST1} of the first host material included in the emitting layer EML, may be higher or lower than them, or may be equal to one of them. The electron affinity EA_{HTL} of the hole-transporting layer HTL may be between the electron affinity EA_{DPT1} of the first dopant and the electron affinity EA_{HST1} of the first host material included in the emitting layer EML, may be higher or lower than them, or may be equal to one of them. The ionization energy IE_{ETL} of the electron-transporting layer may be between the ionization energy IE_{DPT2} of the second dopant and the ionization energy IE_{HST2} of the second host material included in the charge-transporting layer CEL, may be higher or lower than them, or may be equal to one of them. The electron affinity EA_{ETL} of the electron-transporting layer ETL may be between the electron affinity EA_{DPT2} of the second dopant and the electron affinity EA_{HST2} of the second host material, may be higher or lower than them, or may be equal to one of them.

In the organic EL element OLED described with reference to FIGS. 3 and 4, the ionization energy IE_{DPT1} of the first dopant may be equal to or higher than the ionization energy IE_{HST1} of the first dopant included in the emitting layer EML. The electron affinity EA_{DPT1} of the first dopant may be between the ionization energy IE_{DPT2} of the second dopant and the ionization energy IE_{HST2} of the second host material included in the charge-escape layer CEL, may be higher than them, or may be equal to one of them. The ionization energy IE_{HST1} of the first host material included in the emitting layer EML may be between the ionization energy IE_{DPT2} of the second dopant and the ionization energy IE_{HST2} of the second host material included in the charge-escape layer CEL, may be lower than them, or may be equal to one of them. The electron affinity EA_{DPT1} of the first dopant included in the emitting layer EML may be equal to or higher than the electron affinity EA_{HST1} of the first host material included in the emitting layer EML. The electron affinity EA_{DPT1} of the first dopant included in the emitting layer EML may be higher or lower than the electron affinity EA_{DPT2} of the second dopant and the electron affinity EA_{DPT2} of the second host material, or may be equal to one of them.

In the organic EL elements OLED described with reference to FIGS. 3 and 4, the electron affinity EA_{HTL} of the hole-transporting layer HTL may be between the electron affinity EA_{DPT2} of the second dopant and the electron affinity EA_{HST2} of the second host material included in the charge-escape layer CEL, or may be higher or lower than them, or may be equal to one of them. The ionization energy IE_{HTL} of the hole-transporting layer HTL may be between the ionization energy IE_{DPT2} of the second dopant and the ionization energy IE_{HST2} of the second host material included in the charge-escape layer CEL, may be higher or lower than them, or may be equal to one of them. The ionization energy IE_{ETL} of the electron-transporting layer ETL may be between the ionization energy IE_{DPT1} of the first dopant and the ionization energy IE_{DPT1} of the first host material included in the emitting layer, may be higher or lower than them, or may be equal to one of them. The electron affinity EA_{ETL} of the electron-transporting layer ETL may be between the electron affinity EA_{DPT1} of the first dopant and the electron affinity EA_{HST1} of the first host material included in the emitting layer, may be higher or lower than them, or may be equal to one of them.

The above-described organic EL elements can be applied to various organic EL devices. For example, the organic EL elements OLED can be used in an organic EL display, an illuminating device such as interior or exterior illuminating device and backlight for a display panel, a writing device for writing a latent image on a photoconductor drum, or a transmitter utilized for optical communication. Described below are Examples in which the organic EL elements OLED are applied to organic EL displays.

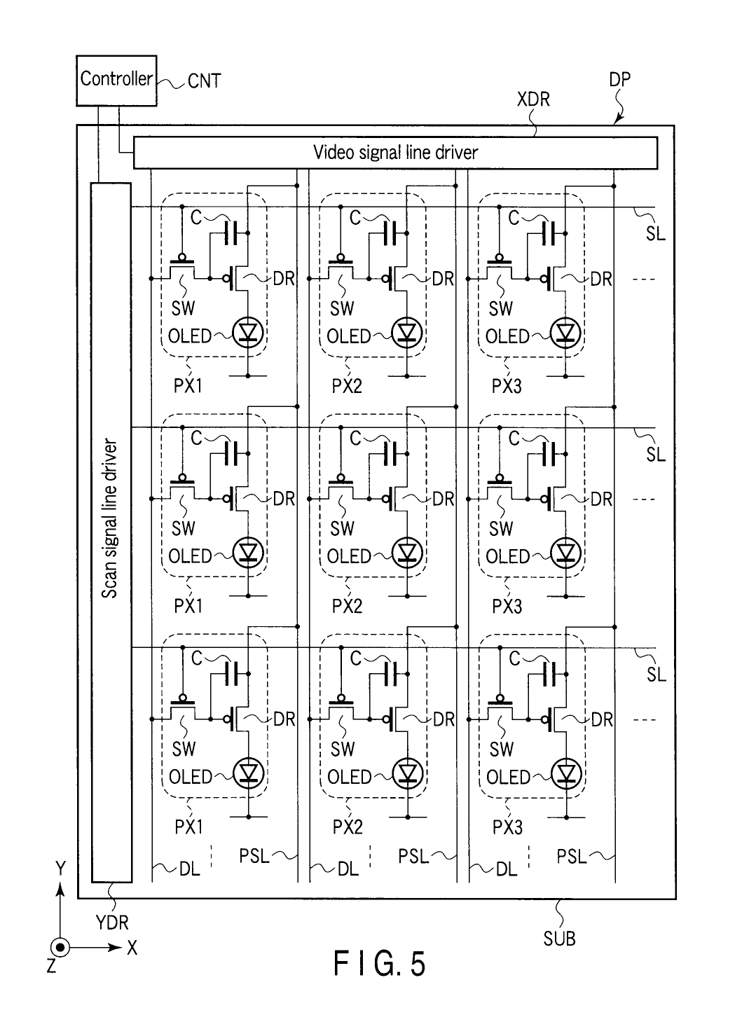

FIG. 5 is a plan view schematically showing an organic EL device according to an embodiment.

The display shown in FIG. 5 is a top emission-typed organic EL display that employs an active matrix-driving method. The display includes a display panel DP, a video signal line driver XDR, a scan signal line driver YDR, and a controller CNT.

The display panel DP includes a substrate SUB, scan signal lines SL, video signal lines DL, power supply lines PSL, and pixels PX1 to PX3. In FIG. 5, the X direction is parallel with a main surface of the substrate, the Y direction is parallel with the main surface of the substrate and crosses the X direction, and Z direction is perpendicular to the X and Y direction.

The scan signal lines SL extend in the X direction and are arranged in the Y direction. The video signal lines DL extend in the Y direction and are arranged in the X direction.

The power supply lines PSL extend in the Y direction and are arranged in the X direction. The power supply lines PSL may extend in the X direction and are arranged in the Y direction.

The pixels PX1 to PX3 are arranged in a matrix corresponding to the arrangement of the intersections of the scan signal lines SL and the video signal lines DL. Here, the pixels PX1 to PX3 form columns each extending in the Y direction. The columns of the pixels PX1, the columns of the pixels PX2, and the columns of the pixels PX3 are arranged in the X direction to form a stripe pattern.

The pixels PX1 to PX3 have different luminous colors. Each of the pixels PX1 to PX3 includes a drive transistor DR, a switch SW, a capacitor C and an organic EL element OLED.

The drive transistor DR is a p-channel thin-film transistor in this embodiment. The source of the drive transistor DR is connected to the power supply line PSL. Note that the power supply line PSL is electrically connected to a high-potential power supply terminal.

The switch SW is a p-channel thin-film transistor in this embodiment. The switch SW is connected between the video signal line DL and the gate of the drive transistor DR and has a gate connected to the scan signal line SL.

The capacitor C is a thin-film capacitor in this embodiment. The capacitor C is electrically connected between the gate and source of the drive transistor DR.

The organic EL element OLED is so designed as that described with reference to FIG. 1 or 3. The organic EL element OLED has an anode electrically connected to the drain of the drive transistor DR and a cathode connected to a low-potential power supply terminal.

The pixels PX1 to PX3 are different in luminous color from one another. For example, the pixel PX1 emits a red-colored light, the pixel PX2 emits green-colored light, and the pixel PX3 emit red-colored light.

The video signal line driver XDR and the scan signal line driver YDR are mounted on the substrate SUB. To be more specific, the video signal line driver XDR and the scan signal line driver YDR are connected to the display panel DP in the chip-on-glass (COG) manner. Instead, the video signal line driver XDR and the scan signal line driver YDR may be connected to the display panel DP by using the tape carrier package (TCP). Alternatively, The video signal line driver XDR and the scan signal line driver YDR may be formed on the substrate SUB.

The video signal lines DL are connected to the video signal line driver XDR. In this embodiment, the power supply lines PSL are further connected to the video signal line driver XDR. The video signal line driver XDR outputs voltage signals as video signals to the video signal lines DL, and outputs a supply voltage to the power supply lines PSL.

The scan signal lines SL are connected to the scan signal line driver YDR. The scan signal line driver YDR outputs voltage signals as scan signals to the scan signal lines SL1 and SL2, respectively.

The video signal lines driver XDR and the scan signal lines driver YDR are connected to the controller CNT. The controller CNT supplies control signals for controlling the operation to the video signal line driver X and supplies source voltage and control signals for controlling the operation to the scan signal line driver YDR.

Although the pixels PX1 to PX3 employ a simple circuit structure, other circuit structures may be employed. Further, employed here is a voltage-driven system in which video signals are supplied as voltage signals, a current-driven system may be employed in which video signals are supplied as current signals.

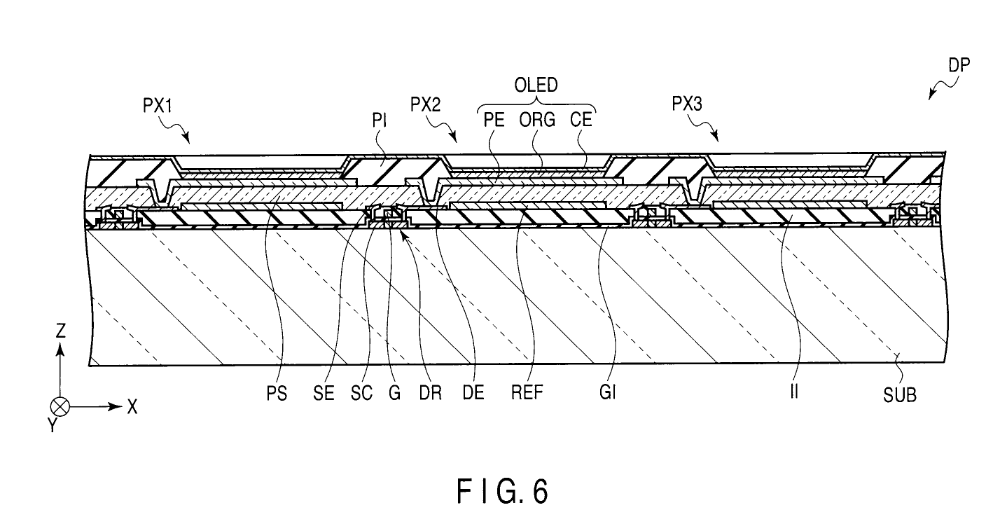

FIG. 6 is a sectional view schematically showing an example of a structure that can be employed in the organic EL device shown in FIG. 5.

FIG. 6 shows a cross section of the display panel DP. The display panel DP includes an insulating substrate SUB such as glass or plastic substrate. An undercoat layer (not shown) is formed on the substrate SUB. The undercoat layer includes, for example, an SiNₓ layer and an SiOₓ layer stacked on the substrate SUB in this order.

On the undercoat layer, formed is a semiconductor pattern made of, for example, polysilicon containing impurities. Parts of the semiconductor pattern are utilized as the semiconductor layers SC. In each semiconductor layer SC, impurity diffusion regions utilized as source and drain are formed. Other parts of the semiconductor pattern are utilized as the bottom electrodes of the capacitors C described with reference to FIG. 5. The bottom electrodes are arranged correspondently with the pixels PX1 to PX3 described with reference to FIG. 5.

The semiconductor pattern is covered with the gate insulator GI. The gate insulator GI can be formed from, for example, tetraethyl orthosilicate (TEOS).

On the gate insulator GI, the scan signal lines SL described with reference to FIG. 5 are formed. The scan signal lines SL is made of, for example, MoW.

On the gate insulator GI, the top electrodes of the capacitors C are further arranged. The top electrodes are arranged correspondently with the pixels PX1 to PX3 and face the bottom electrodes. The top electrodes are made of MoW, for example. The top electrodes can be formed in the same step as that for the scan signal lines SL.

The bottom electrodes, the top electrodes, and the gate insulator GI interposed therebetween form capacitors C described with reference to FIG. 5. The top electrodes of the capacitors C include extensions G. Each extension G intersects a part of the semiconductor layer SC. The intersection of the extension G and the semiconductor layer SC form the drive transistor DR. Note that the extension G is the gate of the drive transistor DR. The scan signal line SL intersect other semiconductor layers SC. Each intersection of the scan signal line SL and the semiconductor layer SC form the switch SW described with reference to FIG. 5.

The gate insulator GI, the scan signal lines SL, and the top electrodes are covered with the interlayer insulating film II. For example, the interlayer insulating film II is an SiOₓ layer formed by plasma chemical vapor deposition (CVD).

On the interlayer insulating film II, source electrodes SE, drain electrodes DE, and the video signal lines DL and the power supply lines described with reference to FIG. 5 are formed. Some of the source electrodes SE are connected between the sources of the drive transistors DR and the power supply lines PSL described with reference to FIG. 5. Other source electrodes SE are connected between the sources of the switches SW described with reference to FIG. 5 and the gates G of the drive transistors DR.

The source electrodes SE, the drain electrodes DE, and the video signal lines DL and power supply lines PSL described with reference to FIG. 5 have, for example, a three-layer structure of Mo/Al/Mo. These components can be formed in the same step.

On the interlayer insulator II, reflective layers REF are further arranged. The reflective layers REF are made of, for example, metal or alloy such as aluminum.

A passivation layer PS covers the source electrodes SE, the drain electrodes DE and the reflective layers REF in addition to the video signal lines DL and the power supply lines PSL described with reference to FIG. 5. The passivation layer PS is made of, for example, SiNₓ.

On the passivation layer PS, pixel electrodes PE are arranged correspondingly with the pixels PX1 to PX3. Each pixel electrode PE is connected via the contact hole formed in the passivation layer PS to the drain electrode DE that is connected to the drain of the drive transistor DR.

In this embodiment, the pixel electrodes PE are back electrodes. Also, in this embodiment, the pixel electrodes PE are anodes. As material of the pixel electrodes PE, for example, transparent conductive oxides such as indium tin oxide (ITO) can be used.

On the passivation layer PS, an insulating partition layer PI is further formed. The insulating partition layer PI is provided with through-holes at positions corresponding to the pixel electrodes PE. Alternatively, the insulating partition layer PI is provided with slits at positions corresponding to columns of the pixel electrodes PE. As an example, it is supposed that through-holes are formed in the insulating partition layer PI at positions corresponding to the pixel electrodes PE.

The insulating partition layer PI is, for example, an organic insulating layer. The insulating partition layer PI can be formed by using photolithography technique, for example.

On the pixel electrodes PE, the organic layer ORG including emitting layers is formed. The organic layer ORG includes the emitting layer EML, the electron-transporting layer, etc. that are described with reference to FIG. 1 or 3.

The insulating partition layer PI and the organic layers ORG are covered with a counter electrode CE. In this embodiment, the counter electrode CE is a front common electrode shared among the pixels PX1 to PX3. In this embodiment, the counter electrode CE serves as a cathode. For example, an electrode wire (not shown) is formed on the layer on which the video signal lines DL are formed, and the counter electrode CE is electrically connected to the electrode wire via the contact hole formed in the passivation layer PS and the insulating partition layer PI.

The pixel electrodes PE, the organic layer ORG, and the counter electrode CE form the organic EL elements OLED arranged correspondently with the pixel electrodes PE. Each organic EL element has the structure described with reference to FIG. 1 or 3.

Note that in this display panel DP, the hole injection layer HIL, the hole-transporting layer HTL, the charge-escape layer CEL, the electron-transporting layer ETL, the electron injection layer EIL and the cathode CTD described with reference to FIG. 1 or 3 need not be divided at a position between the pixels.

In the organic EL display, the organic EL elements OLED are so designed as that described with reference to FIGS. 1 and 2 or FIGS. 3 and 4. Therefore, in this organic EL display, the triplet-triplet annihilation can be effectively utilized for increasing the inner quantum efficiency, and thus a higher luminance, a reduced power consumption, a longer life-time, etc. are possible.

Various modifications can be made to the organic EL display.

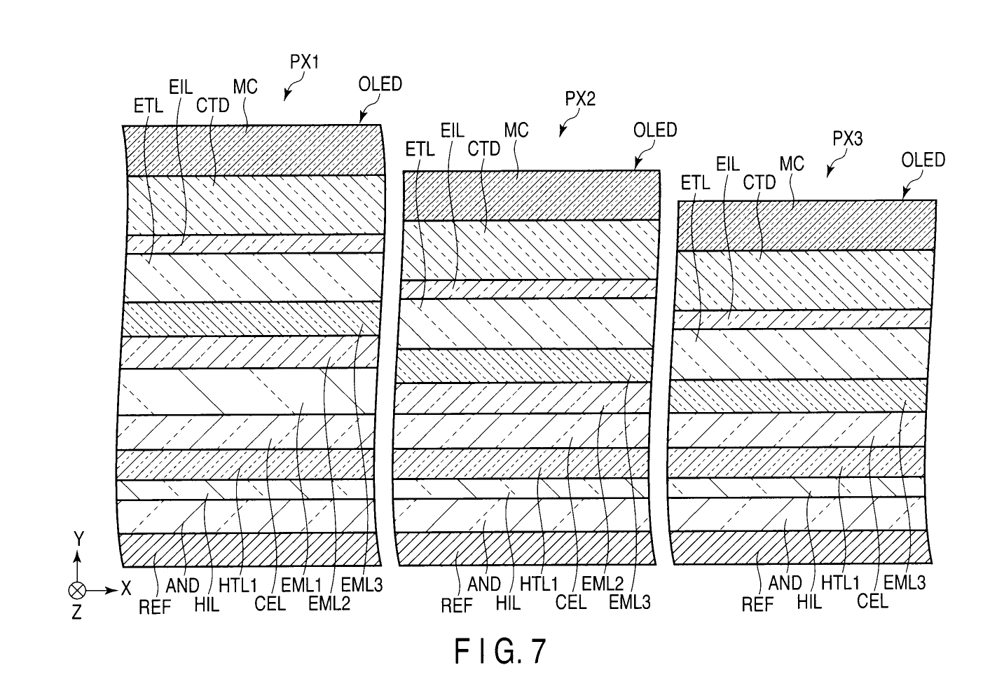

FIG. 7 is a sectional view schematically showing an organic EL device according to a modification. FIG. 7 shows the display panel DP from which some of the components are omitted.

The structure shown in FIG. 7 is the same as that described with reference to FIGS. 3 to 6 except for the following.

In the structure shown in FIG. 7, the organic EL element of the pixel PX1 includes emitting layers EML1 to EML3 as an emitting layer, the organic EL element of the pixel PX2 includes the emitting layers EML2 and EML3 as an emitting layer, and the organic EL element of the pixel PX1 includes the emitting layers EML3 as an emitting layer. In the organic EL element OLED of the pixel PX1, the emitting layer EML2 is interposed between the emitting layer EML1 and the electron-transporting layer ETL, and the emitting layer EML3 is interposed between the emitting layer EML2 and the electron-transporting layer ETL. In the organic EL element OLED of the pixel PX2, the emitting layer EML3 is interposed between the emitting layer EML2 and the electron-transporting layer ETL. The emitting layer 2 emits light having a wavelength shorter than the wavelength of light that the emitting layer EML1 emits. The emitting layer 3 emits light having a wavelength shorter than the wavelength of light that the emitting layer EML2 emits. For example, the luminous color of the emitting layer EML1 is red, the luminous color of the emitting layer EML2 is green, and the luminous color of the emitting layer EML3 is blue.

In the case of employing this structure, it is possible to utilize in the pixel PX1 the light emitted by the emitting layer EML3 as excitation light for causing light emission of at least one of the emitting layers EML1 and EML2 and to utilize in the pixel PX2 the light emitted by the emitting layer EML2 as excitation light for causing light emission of the emitting layer EML1. Therefore, the pixel PX1 can display almost the same color as the luminous color of the emitting layer EML1 in spite of the fact that the emitting layers EML1 to EML3 having different luminous colors are stacked on top of each other. Similarly, the pixel PX2 can display almost the same color as the luminous color of the emitting layer EML2 in spite of the fact that the emitting layers EML2 and EML3 having different luminous colors are stacked on top of each other.

In the case of employing the above structure, the emitting layer EML2 need not be divided at a position between the pixels PX1 and PX2. The emitting layer EML3 need not be divided at positions between the pixels PX1 and PX2, between the pixels PX2 and PX3 and between the pixels PX3 and PX1 similar to the hole injection layer HIL, the hole-transporting layer HTL, the electron-transporting layer ETL, the electron injection layer EIL, the cathode CTD, and the optical matching layer MC described below.

The structure shown in FIG. 7 further includes an optical matching layer MC. The optical matching layer MC is placed such that the anode AND, the cathode CTD and the layers interposed therebetween are sandwiched between the matching layer MC and the reflective layer REF. The optical matching layer MC is a light-transmitting layer. One of the main surfaces of the optical matching layer MC that does not face the reflective layer REF serves as a reflective surface having a light-transmitting property. The thickness of the optical matching layer MC is appropriately set such that the light to be extracted causes optical resonance in each of the pixels PX1 to PX3. As the optical matching layer MC, a transparent inorganic insulating layer such as SiN layer, a transparent inorganic conductive layer such as ITO layer, or a transparent organic layer such as an organic layer or layers included in the organic layer ORG can be used.

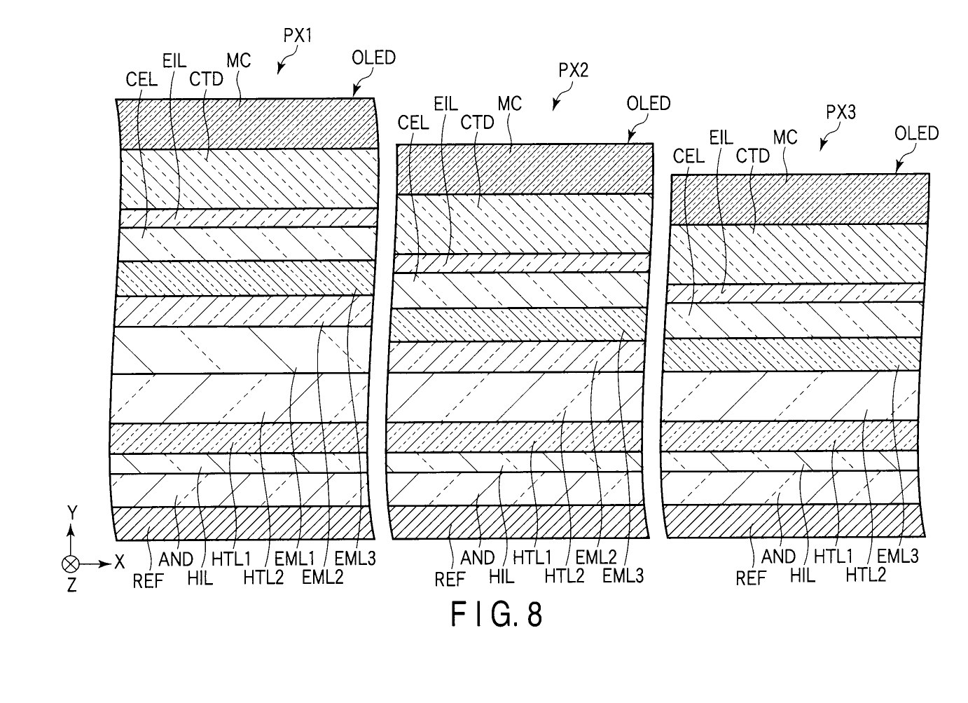

FIG. 8 is a sectional views schematically showing an organic EL device according to another modification. FIG. 8 shows the display panel DP from which some of the components are omitted.

The structure shown in FIG. 8 is the same as that described with reference to FIGS. 1, 2, 5 and 6 except for the following.

In the structure shown in FIG. 8, the electron-transporting layer ETL is omitted.

The structure shown in FIG. 8 includes hole-transporting layers HTL1 and HTL2 instead of the hole-transporting layer HTL. The hole-transporting layer HTL1 is interposed between the hole-transporting layer HTL2 and the hole injection layer HIL. The hole-transporting layer HTL1 is made of an organic material and typically has an ionization energy between the work function of the anode AND and the ionization energy of each of the emitting layers EML1 to EML3. The hole-transporting layer HTL2 is made of an organic material and typically has an ionization energy between the ionization energy of the hole-transporting layer HTL1 and the ionization energy of each of the emitting layers EML1 to EML3.

Similar to the structure shown in FIG. 7, in the structure shown in FIG. 8, the organic EL element of the pixel PX1 includes emitting layers EML1 to EML3 as an emitting layer, the organic EL element of the pixel PX2 includes the emitting layers EML2 and EML3 as an emitting layer, and the organic EL element of the pixel PX1 includes the emitting layers EML3 as an emitting layer. In the organic EL element OLED of the pixel PX1, the emitting layer EML2 is interposed between the emitting layer EML1 and the charge-escape layer CEL, and the emitting layer EML3 is interposed between the emitting layer EML2 and the charge-escape layer CEL. In the organic EL element OLED of the pixel PX2, the emitting layer EML3 is interposed between the emitting layer EML2 and the charge-escape layer CEL. The emitting layer 2 emits light having a wavelength shorter than the wavelength of light that the emitting layer EML1 emits. The emitting layer 3 emits light having a wavelength shorter than the wavelength of light that the emitting layer EML2 emits. For example, the luminous color of the emitting layer EML1 is red, the luminous color of the emitting layer EML2 is green, and the luminous color of the emitting layer EML3 is blue.

In the case of employing this structure, it is possible to utilize in the pixel PX1 the light emitted by the emitting layer EML3 as excitation light for causing light emission of at least one of the emitting layers EML1 and EML2 and to utilize in the pixel PX2 the light emitted by the emitting layer EML2 as excitation light for causing light emission of the emitting layer EML1. Therefore, the pixel PX1 can display almost the same color as the luminous color of the emitting layer EML1 in spite of the fact that the emitting layers EML1 to EML3 having different luminous colors are stacked on top of each other. Similarly, the pixel PX2 can display almost the same color as the luminous color of the emitting layer EML2 in spite of the fact that the emitting layers EML2 and EML3 having different luminous colors are stacked on top of each other.

In the case of employing the above structure, the emitting layer EML2 need not be divided at a position between the pixels PX1 and PX2. The emitting layer EML3 need not be divided at positions between the pixels PX1 and PX2, between the pixels PX2 and PX3 and between the pixels PX3 and PX1 similar to the hole injection layer HIL, the hole-transporting layer HTL, the charge-escape layer CEL, the electron-transporting layer ETL, the electron injection layer EIL, the cathode CTD, and the optical matching layer MC described below.

The structure shown in FIG. 8 further includes the optical matching layer MC described with reference to FIG. 7. The optical matching layer MC is placed such that the anode AND, the cathode CTD and the layers interposed therebetween are sandwiched between the matching layer MC and the reflective layer REF. The optical matching layer MC is a light-transmitting layer. One of the main surfaces of the optical matching layer MC that does not face the reflective layer REF serves as a reflective surface having a light-transmitting property. The thickness of the optical matching layer MC is appropriately set such that the light to be extracted causes optical resonance in each of the pixels PX1 to PX3. As the optical matching layer MC, a transparent inorganic insulating layer such as SiN layer, a transparent inorganic conductive layer such as ITO layer, or a transparent organic layer such as an organic layer or layers included in the organic layer ORG can be used.

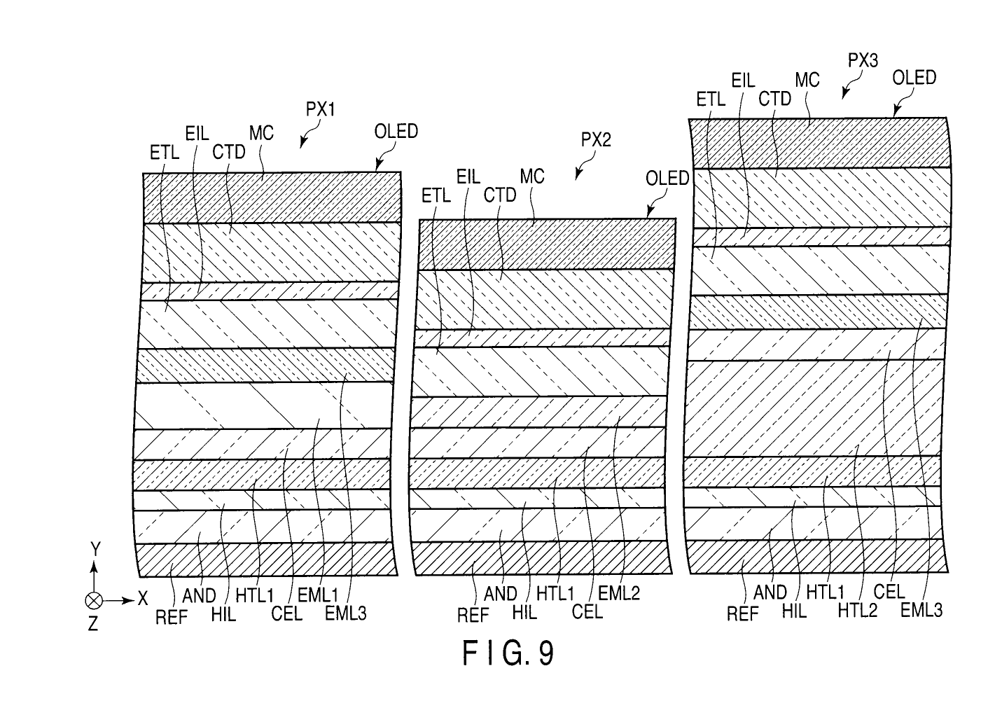

FIG. 9 is a sectional views schematically showing an organic EL device according to another modification. FIG. 9 shows the display panel DP from which some of the components are omitted.

The structure shown in FIG. 9 is the same as that described with reference to FIG. 7 except for the following.

In the structure shown in FIG. 9, the organic EL elements OLED of the pixels PX1 and PX2 include a hole-transporting layer HTL1 instead of the hole-transporting layer HTL. The organic EL elements OLED of the pixel PX3 includes a hole-transporting layer HTL2 in addition to the hole-transporting layer HTL1 instead of the hole-transporting layer HTL. In the pixel PX3, the hole-transporting layer HTL2 is interposed between the hole-transporting layer HTL1 and the charge-escape layer CEL. The hole-transporting layer HTL1 is made of an organic material and typically has an ionization energy between the work function of the anode AND and the ionization energy of each of the emitting layers EML1 to EML3. The hole-transporting layer HTL2 is made of an organic material and typically has an ionization energy between the ionization energy of the hole-transporting layer HTL1 and the ionization energy of each of the emitting layers EML1 to EML3.

In the structure shown in FIG. 9, the pixel PX1 does not include the emitting layer EML2, and the pixel PX3 does not include the emitting layer EML3.

As above, in the structure shown in FIG. 7, the emitting layer EML2 can be omitted from the pixel PX1, and the emitting layer EML3 can be omitted from the pixel PX2. Further, in the structure shown in FIG. 7, the pixel PX3 can further includes the hole-transporting layer HTL2. Therefore, carrier balances in the emitting layers EML1 to EML3 and the optical thicknesses of the structures in which optical resonance should be caused can be adjusted by changing the multilayer structures, for example, as described with reference to FIG. 9.

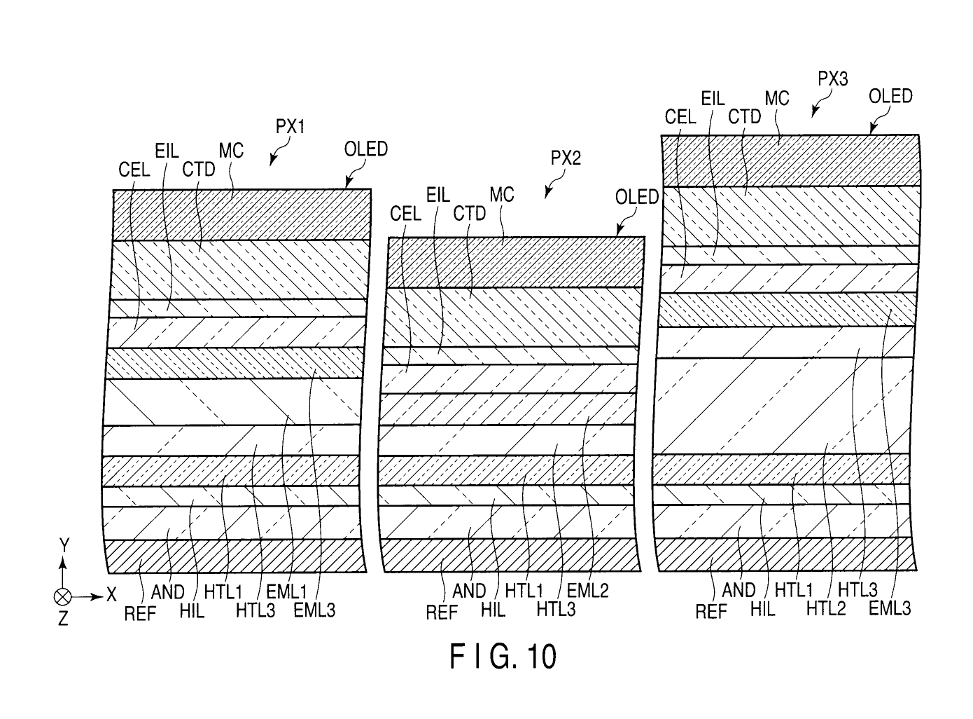

FIG. 10 is a sectional views schematically showing an organic EL device according to another modification.

FIG. 10 shows the display panel DP from which some of the components are omitted.

The structure shown in FIG. 10 is the same as that described with reference to FIG. 8 except for the following.

In the structure shown in FIG. 10, the organic EL elements OLED of the pixels PX1 and PX2 include a hole-transporting layer HTL3 instead of the hole-transporting layer HTL2. The organic EL elements OLED of the pixel PX3 further includes the hole-transporting layer HTL3. In the pixel PX3, the hole-transporting layer HTL3 is interposed between the hole-transporting layer HTL2 and the emitting layer EML3. The hole-transporting layer HTL3 is made of an organic material and typically has an ionization energy between the ionization energy of the hole-transporting layer HTL2 and the ionization energy of each of the emitting layers EML1 to EML3.

In the structure shown in FIG. 10, the pixel PX1 does not include the emitting layer EML2, and the pixel PX3 does not include the emitting layer EML3.

As above, in the structure shown in FIG. 8, the emitting layer EML2 can be omitted from the pixel PX1, and the emitting layer EML3 can be omitted from the pixel PX2. Further, in the structure shown in FIG. 8, the hole-transporting layer HTL2 can be omitted from some of the pixels PX1 to PX3 and each of the pixels PX1 to PX3 can further includes the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 10.

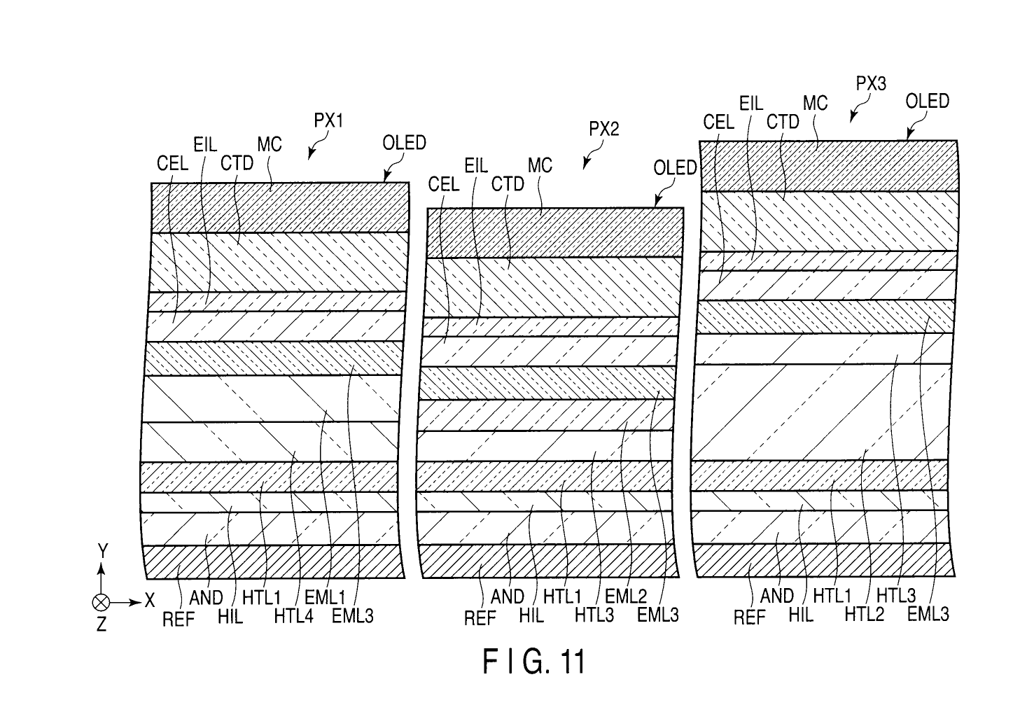

FIG. 11 is a sectional views schematically showing an organic EL device according to another modification. FIG. 11 shows the display panel DP from which some of the components are omitted.

The structure shown in FIG. 11 is the same as that described with reference to FIG. 10 except for the following.

In the structure shown in FIG. 11, the organic EL element OLED of the pixel PX1 includes a hole-transporting layer HTL4 instead of the hole-transporting layer HTL3. The hole-transporting layer HTL4 is made of an organic material and typically has an ionization energy between the ionization energy of the hole-transporting layer HTL1 and the ionization energy of the emitting layer EML1.

In the structure shown in FIG. 11, the pixel PX2 further includes the emitting layer EML3. In the pixel PX2, the emitting layer EML3 is interposed between the emitting layer EML2 and the charge-escape layer CEL.

As above, in the structure shown in FIG. 10, the pixels PX1 and PX2 need not include the same hole-transporting layer, i.e., hole-transporting layer HTL3 and can further include the emitting layer EML3. Therefore, carrier balances in the emitting layers EML1 to EML3 and the optical thicknesses of the structures in which optical resonance should be caused can be adjusted by changing the multilayer structures, for example, as described with reference to FIG. 11.

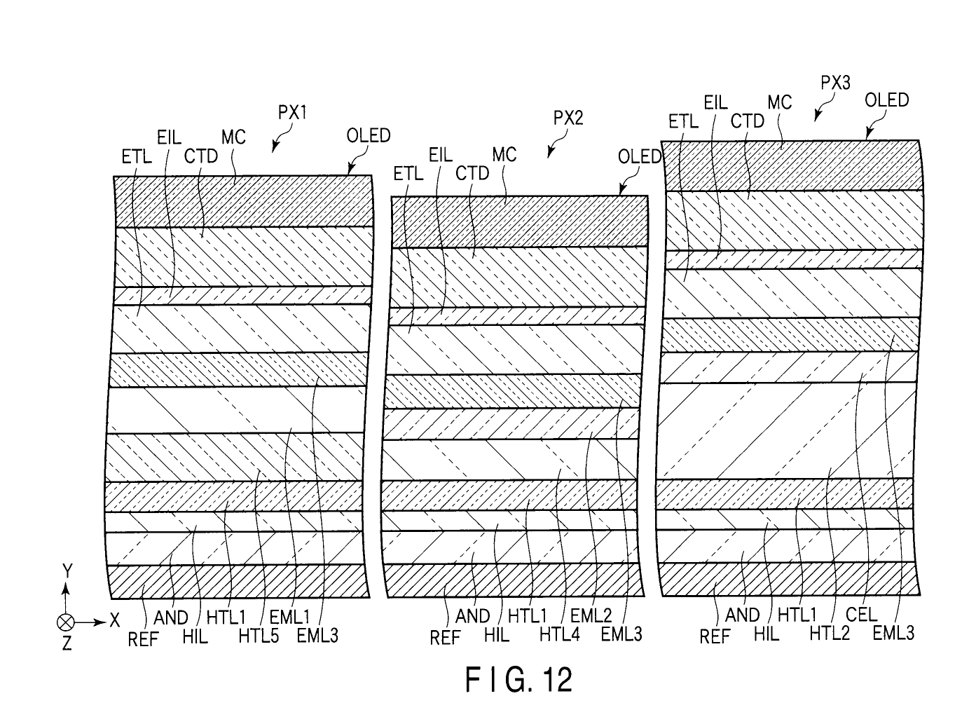

FIG. 12 is a sectional views schematically showing an organic EL device according to another modification. FIG. 12 shows the display panel DP from which some of the components are omitted.

The structure shown in FIG. 12 is the same as that described with reference to FIG. 9 except for the following.

In the structure shown in FIG. 12, the organic EL element OLED of the pixel PX1 includes a hole-transporting layer HTL5 instead of the charge-escape layer CEL. The hole-transporting layer HTL5 is made of an organic material and typically has an ionization energy between the ionization energy of the hole-transporting layer HTL1 and the ionization energy of the emitting layer EML1.

In the structure shown in FIG. 12, the organic EL element OLED of the pixel PX2 includes the hole-transporting layer HTL4 instead of the charge-escape layer CEL and further includes the emitting layer EML3. In the pixel PX2, the emitting layer EML3 is interposed between the emitting layer EML2 and the electron-transporting layer ETL.

As above, in the structure shown in FIG. 9, the pixel PX2 can further include the emitting layer EML3, and the pixels PX1 and PX2 can further include the hole-transporting layers HTL5 and HTL4, respectively, instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 12.

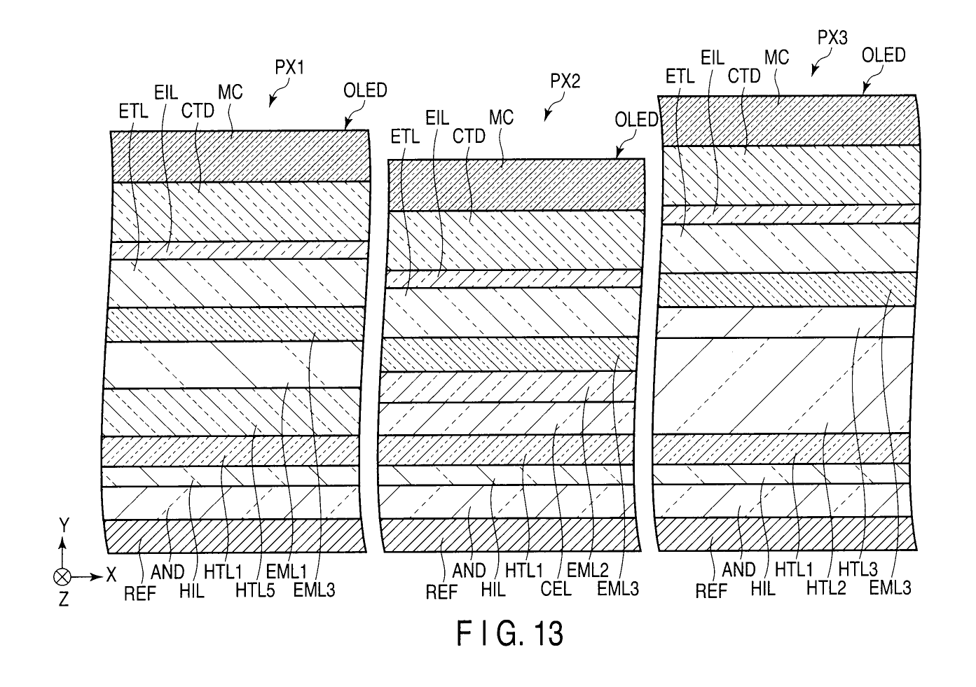

FIG. 13 is a sectional views schematically showing an organic EL device according to another modification. FIG. 13 shows the display panel DP from which some of the components are omitted.

The structure shown in FIG. 13 is the same as that described with reference to FIG. 12 except for the following.

In the structure shown in FIG. 13, the organic EL element OLED of the pixel PX2 includes the charge-escape layer CEL instead of the hole-transporting layer HTL4. Further, in the structure shown in FIG. 13, the pixel PX3 includes the hole-transporting layer HTL3 instead of the charge-escape layer CEL.

As above, in the structure shown in FIG. 12, the pixel PX2 can include the charge-escape layer CEL instead of the hole-transporting layer HTL4, and the pixel PX3 can include the hole-transporting layer HTL4 instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 13.

Specifically, in the case of employing this structure, the optical thicknesses of the structures in which optical resonance should be caused can be adjusted utilizing the hole-transporting layers HTL1, HTL2, HTL3 and HTL5, the emitting layers EML1 to EML3 and the charge-escape layer CEL.

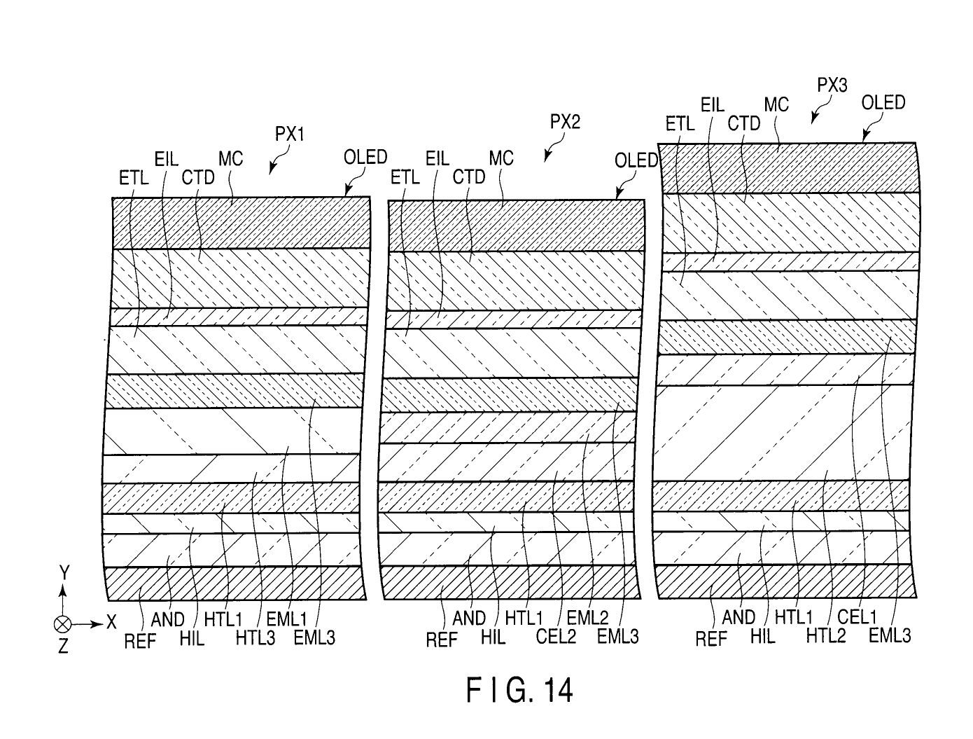

FIG. 14 is a sectional views schematically showing an organic EL device according to another modification. FIG. 14 shows the display panel DP from which some of the components are omitted.

The structure shown in FIG. 14 is the same as that described with reference to FIG. 12 except for the following.

In the structure shown in FIG. 14, the organic EL element OLED of the pixel PX1 includes the hole-transporting layer HTL3 instead of the hole-transporting layer HTL5. Further, in the structure shown in FIG. 14, the pixel PX2 includes the charge-escape layer CEL instead of the hole-transporting layer HTL4.

As above, in the structure shown in FIG. 12, the pixel PX1 can include the hole-transporting layer HTL3 instead of the hole-transporting layer HTL5, and the pixel PX2 can include the charge-escape layer CEL instead of the hole-transporting layer HTL4. Therefore, carrier balances in the emitting layers EML1 to EML3 and the optical thicknesses of the structures in which optical resonance should be caused can be adjusted by changing the multilayer structures, for example, as described with reference to FIG. 14.

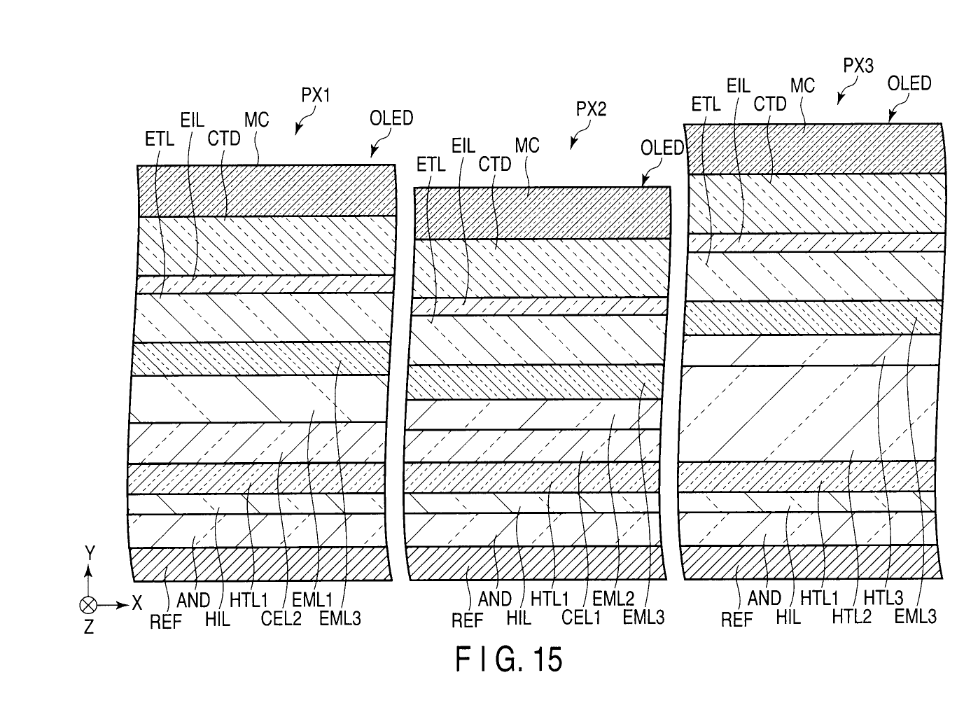

FIG. 15 is a sectional views schematically showing an organic EL device according to another modification. FIG. 15 shows the display panel DP from which some of the components are omitted.

The structure shown in FIG. 15 is the same as that described with reference to FIG. 12 except for the following.

In the structure shown in FIG. 15, the organic EL element OLED of the pixel PX1 includes a charge-escape layer CEL2 instead of the hole-transporting layer HTL5. The layers those described as examples of the charge-escape layer CEL can be used as the charge-escape layer CEL2.

Further, in the structure shown in FIG. 15, the pixel PX2 includes a charge-escape layer CEL1 instead of the hole-transporting layer HTL4. The layers those described as examples of the charge-escape layer CEL can be used as the charge-escape layer CEL1. The charge-escape layers CEL1 and CEL2 are different from each other in at least one of thickness and composition.

In addition, in the structure shown in FIG. 15, the pixel PX3 includes the hole-transporting layer HTL3 instead of the charge-escape layer CEL.

As above, in the structure shown in FIG. 12, the pixel PX1 can include the charge-escape layer CEL2 instead of the hole-transporting layer HTL5, the pixel PX2 can include the charge-escape layer CEL1 instead of the hole-transporting layer HTL4, and the pixel can includes the hole-transporting layer HTL3 instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 15.

In the case of using two or more charge-escape layers different from each other in at least one of thickness and composition, it is easy to maximize the inner quantum efficiencies in two or more pixels having different luminous colors. Since the charge-escape layers CEL1 and CEL2 are used here, it is easy to maximize the inner quantum efficiencies in the pixels PX1 and PX2.

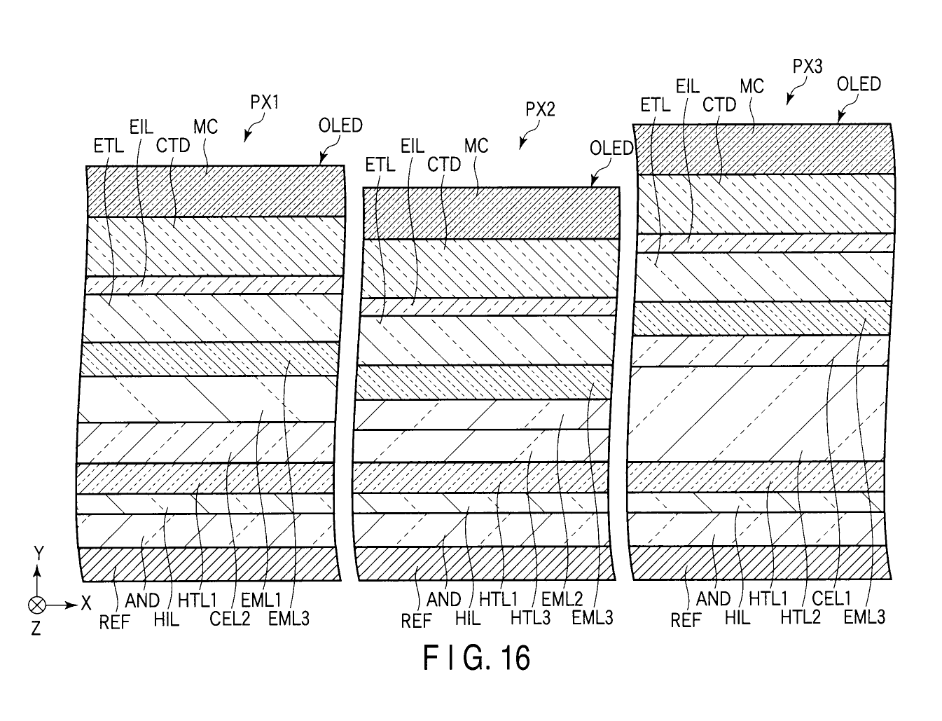

FIG. 16 is a sectional views schematically showing an organic EL device according to another modification. FIG. 16 shows the display panel DP from which some of the components are omitted.

The structure shown in FIG. 16 is the same as that described with reference to FIG. 15 except for the following.

In the structure shown in FIG. 16, the organic EL element OLED of the pixel PX2 includes the hole-transporting layer HTL3 instead of the charge-escape layer CEL1. Further, in the structure shown in FIG. 16, the organic EL element OLED of the pixel PX3 includes the charge-escape layer CEL1 instead of the hole-transporting layer HTL3.

As above, in the structure shown in FIG. 15, the pixel PX2 can include the hole-transporting layer HTL3 instead of the charge-escape layer CEL1, and the pixel PX3 can include the charge-escape layer CEL2 instead of the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 16. Further, in the case of using the charge-escape layers CEL1 and CEL2 in the pixels PX1 and PX3, respectively, as shown in FIG. 16, it is easy to maximize the inner quantum efficiencies in the pixels PX1 and PX3.

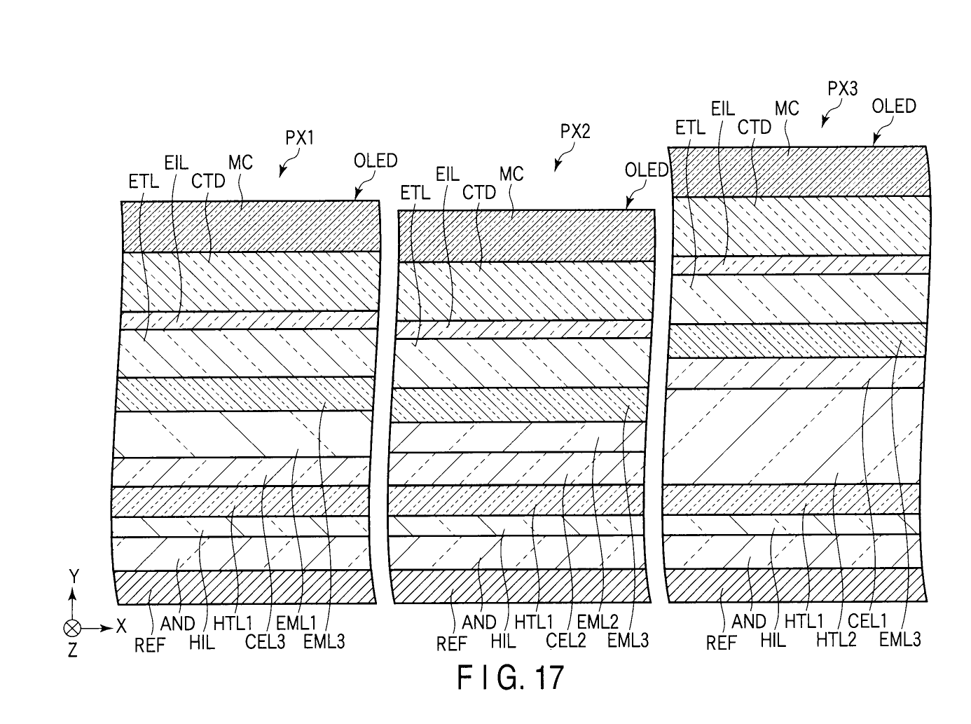

FIG. 17 is a sectional views schematically showing an organic EL device according to another modification. FIG. 17 shows the display panel DP from which some of the components are omitted.

The structure shown in FIG. 17 is the same as that described with reference to FIG. 15 except for the following.

In the structure shown in FIG. 17, the organic EL element OLED of the pixel PX1 includes a charge-escape layer CEL3 instead of the charge-escape layer CEL2. The layers those described as examples of the charge-escape layer CEL can be used as the charge-escape layer CEL3. The charge-escape layers CEL1 to CEL3 are different from one another in at least one of thickness and composition.

Further, in the structure shown in FIG. 17, the organic EL element OLED of the pixel PX2 includes the charge-escape layer CEL2 instead of the charge-escape layer CEL1.

In addition, in the structure shown in FIG. 17, organic EL element OLED of the pixel PX3 includes the charge-escape layer CEL1 instead of the hole-transporting layer HTL2.

As above, in the structure shown in FIG. 15, the pixel PX1 can include the charge-escape layer CEL3 instead of the charge-escape layer CEL2, the pixel PX2 can include the charge-escape layer CEL2 instead of the charge-escape layer CEL1, and the pixel PX3 can include the charge-escape layer CEL1 instead of the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 17. Further, in the case of using the charge-escape layers CEL3 to CEL1 in the pixels PX1 to PX3, respectively, as shown in FIG. 17, it is easy to maximize the inner quantum efficiencies in the pixels PX1 to PX3.

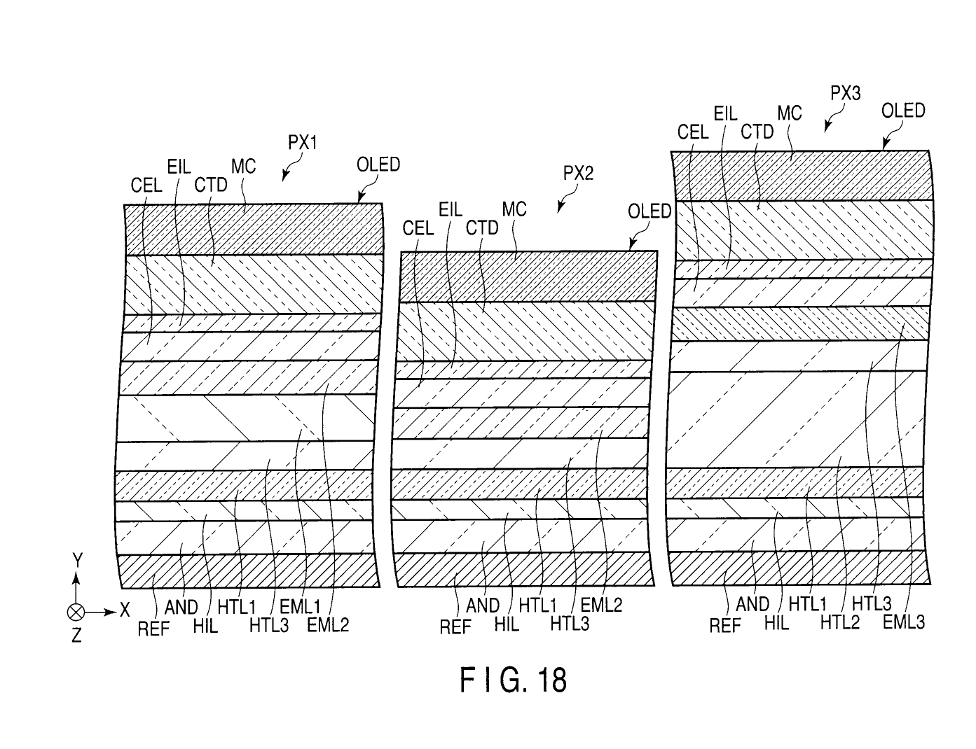

FIG. 18 is a sectional views schematically showing an organic EL device according to another modification. FIG. 18 shows the display panel DP from which some of the components are omitted.

The structure shown in FIG. 18 is the same as that described with reference to FIG. 10 except that the pixel PX1 includes the emitting layer EML2 instead of the emitting layer EML3.

As above, in the structure shown in FIG. 10, the pixel PX1 can include the emitting layer EML2 instead of the emitting layer EML3. Therefore, carrier balances in the emitting layers EML1 to EML3 and the optical thicknesses of the structures in which optical resonance should be caused can be adjusted by changing the multilayer structures, for example, as described with reference to FIG. 18.

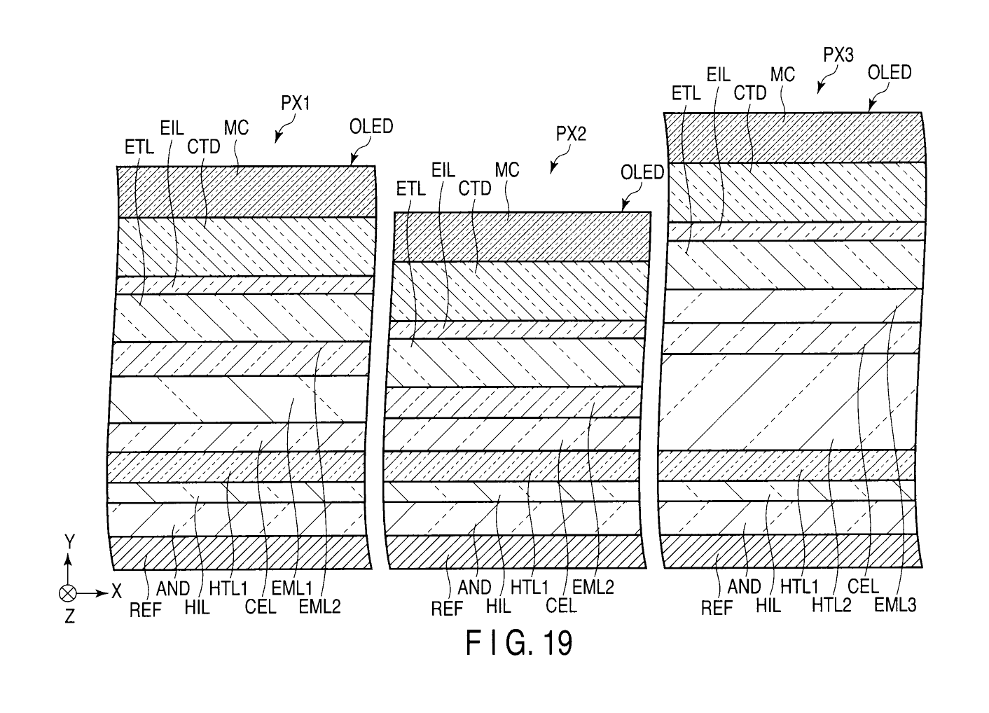

FIG. 19 is a sectional views schematically showing an organic EL device according to another modification. FIG. 19 shows the display panel DP from which some of the components are omitted.

The structure shown in FIG. 19 is the same as that described with reference to FIG. 9 except that the pixel PX1 includes the emitting layer EML2 instead of the emitting layer EML3.

As above, in the structure shown in FIG. 9, the pixel PX1 can include the emitting layer EML2 instead of the emitting layer EML3. Therefore, carrier balances in the emitting layers EML1 to EML3 and the optical thicknesses of the structures in which optical resonance should be caused can be adjusted by changing the multilayer structures, for example, as described with reference to FIG. 19.

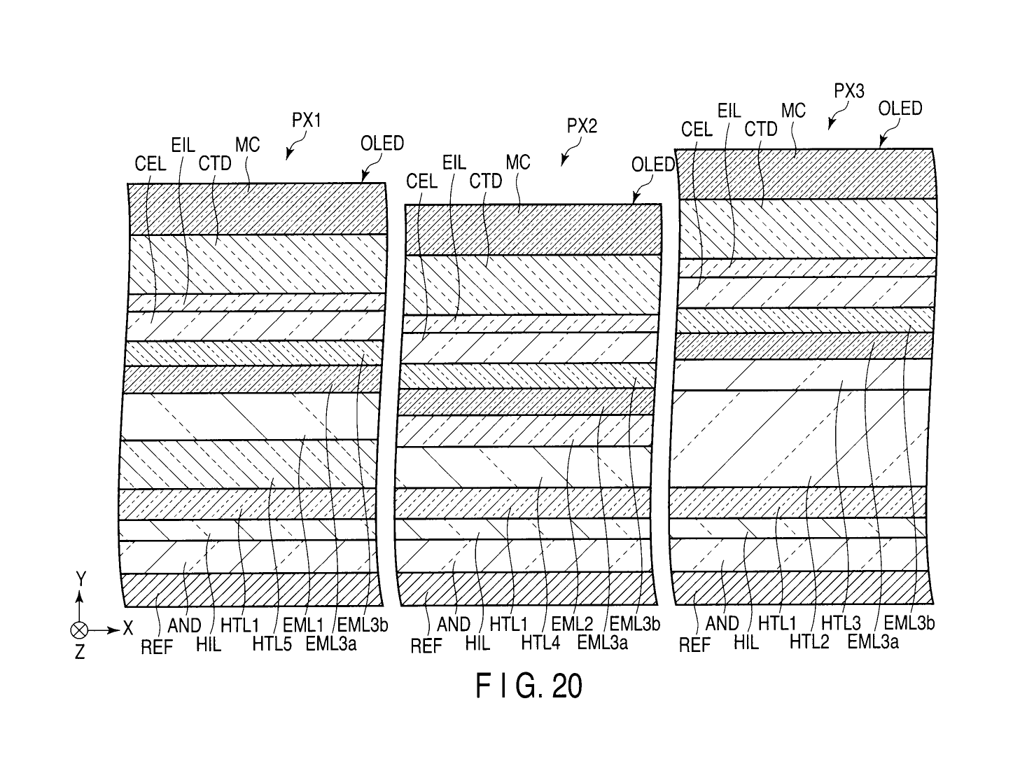

FIG. 20 is a sectional views schematically showing an organic EL device according to another modification. FIG. 20 shows the display panel DP from which some of the components are omitted.

The structure shown in FIG. 20 is the same as that described with reference to FIG. 8 except for the following.

In the structure shown in FIG. 20, the organic EL element OLED of the pixel PX1 includes the hole-transporting layer HTL5 instead of the hole-transporting layer HTL2, the organic EL element OLED of the pixel PX2 includes the hole-transporting layer HTL4 instead of the hole-transporting layer HTL2, and the organic EL element OLED of the pixel PX3 further includes the hole-transporting layer HTL3. In the pixel PX3, the hole-transporting layer HTL3 is interposed between the hole-transporting layer HTL2 and the emitting layer EML3a described later.

Further, in the structure shown in FIG. 20, each organic EL element OLED of the pixels PX1 to PX3 includes emitting layers EML3a and EML3b instead of the emitting layer EML3. The luminous colors of the emitting layers EML3a and EML3b are, for example, blue. The emitting layer EML3a is interposed between the emitting layers EML1 and EML3b. The hole mobility in the emitting layer EML3b is, for example, lower than the hole mobility in the emitting layer EML3a. Alternatively, the level of the highest occupied molecular orbital (HOMO) in the emitting layer EML3b is, for example, higher than the HOMO level in the emitting layer EML3a.

As above, in the structure shown in FIG. 8, the pixel PX1 can include the hole-transporting layer HTL5 instead of the hole-transporting layer HTL2, the pixel PX2 can include the hole-transporting layer HTL4 instead of the hole-transporting layer HTL2, and the pixel PX3 can further include the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 20.

Further, when the emitting layers EML3a and EML3b are provided instead of the emitting layer EML3 as shown in FIG. 20, more holes injected therein can contribute to light emission. Therefore, the drive voltage can be lowered.

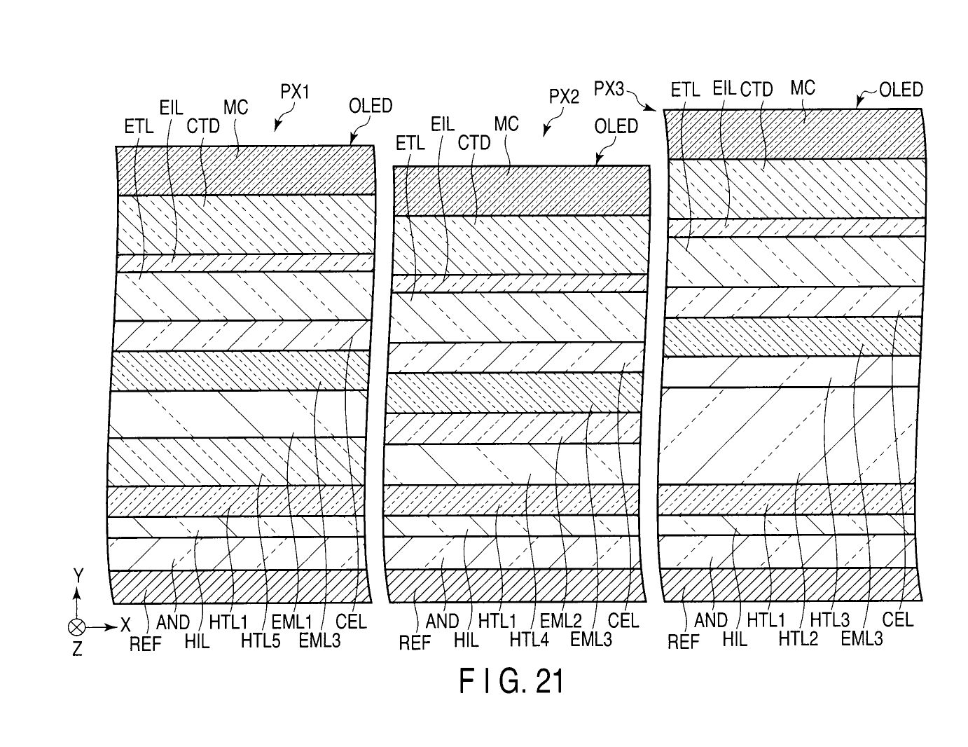

FIG. 21 is a sectional views schematically showing an organic EL device according to another modification. FIG. 21 shows the display panel DP from which some of the components are omitted.

The structure shown in FIG. 21 is the same as that described with reference to FIG. 18 except for the following.

In the structure shown in FIG. 21, each organic EL element OLED of the pixels PX1 to PX3 further includes the electron-transporting layer ETL. The electron-transporting layer ETL is interposed between the charge-escape layer CEL and the electron-transporting layer EIL.

Further, in the structure shown in FIG. 21, the organic EL element OLED of the pixel PX1 includes the hole-transporting layer HTL5 instead of the hole-transporting layer HTL3 and includes the emitting layer EML3 instead of the emitting layer EML2.

In addition, in the structure shown in FIG. 21, the organic EL element OLED of the pixel PX2 includes the hole-transporting layer HTL4 instead of the hole-transporting layer HTL3 and further includes the emitting layer EML3. In the pixel PX3, the emitting layer EML3 is interposed between the emitting layer EML2 and the charge-escape layer CEL.

As above, in the structure shown in FIG. 18, each of the pixels PX1 to PX3 can further include the electron-transporting layer ETL, the pixel PX1 can include the hole-transporting layer HTL5 and the emitting layer EML3 instead of the hole-transporting layer HTL3 and the emitting layer EML2, respectively, and the pixel PX2 can include the hole-transporting layer HTL4 instead of the hole-transporting layer HTL3 and further include the emitting layer EML3. Therefore, carrier balances in the emitting layers EML1 to EML3 and the optical thicknesses of the structures in which optical resonance should be caused can be adjusted by changing the multilayer structures, for example, as described with reference to FIG. 21.

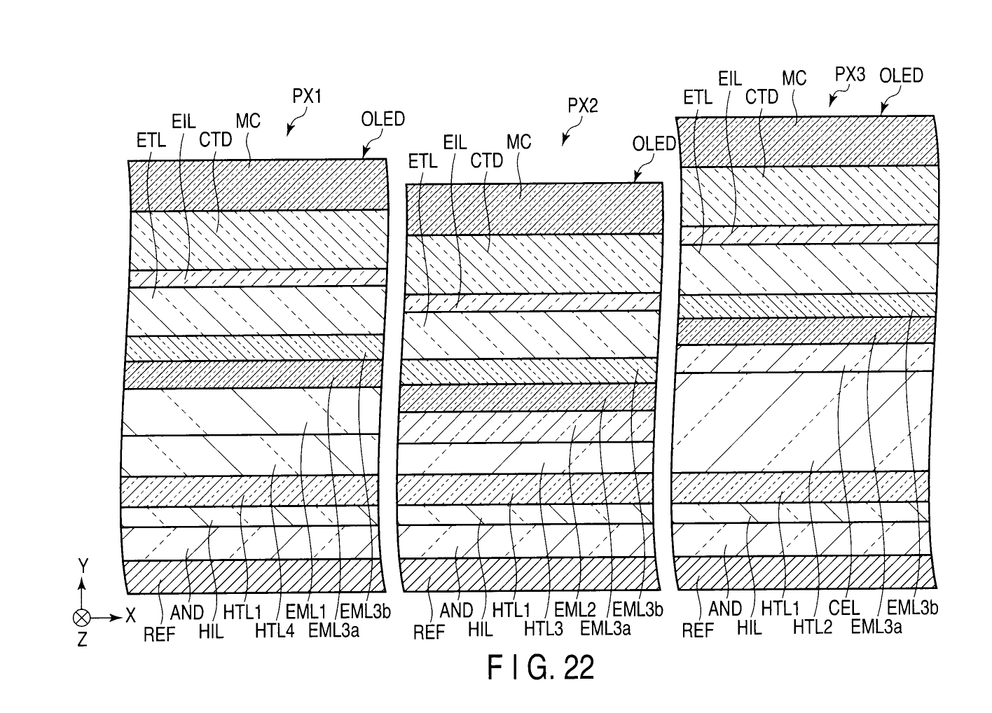

FIG. 22 is a sectional views schematically showing an organic EL device according to another modification. FIG. 22 shows the display panel DP from which some of the components are omitted.

The structure shown in FIG. 22 is the same as that described with reference to FIG. 12 except for the following.

In the structure shown in FIG. 22, each organic EL element OLED of the pixels PX1 to PX3 includes the emitting layers EML3a and EML3b instead of the emitting layer EML3. The emitting layer EML3a is interposed between the emitting layer EML1 and the emitting layer EML3b.

Further, in the structure shown in FIG. 22, the organic EL element OLED of the pixel PX1 includes the hole-transporting layer HTL4 instead of the hole-transporting layer HTL5. In addition, the organic EL element OLED of the pixel PX2 includes the hole-transporting layer HTL3 instead of the hole-transporting layer HTL4.

As above, in the structure shown in FIG. 12, pixel PX1 can include the hole-transporting layer HTL4 instead of the hole-transporting layer HTL5, and the pixel PX2 can include the hole-transporting layer HTL3 instead of the hole-transporting layer HTL4. Therefore, carrier balances in the emitting layers EML1 to EML3 and the optical thicknesses of the structures in which optical resonance should be caused can be adjusted by changing the multilayer structures, for example, as described with reference to FIG. 22.

Further, when the emitting layers EML3a and EML3b are provided instead of the emitting layer EML3 as shown in FIG. 22, more holes injected therein can contribute to light emission. Therefore, the drive voltage can be lowered.

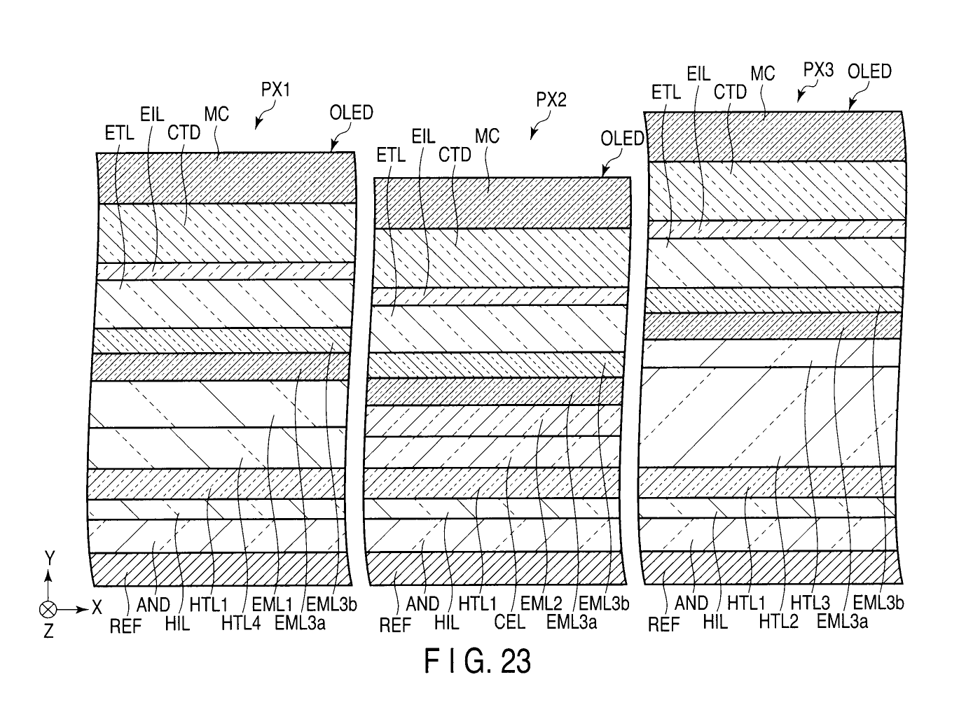

FIG. 23 is a sectional views schematically showing an organic EL device according to another modification. FIG. 23 shows the display panel DP from which some of the components are omitted.

The structure shown in FIG. 23 is the same as that described with reference to FIG. 22 except for the following.

In the structure shown in FIG. 23, the organic EL element OLED of the pixel PX2 includes the charge-escape layer CEL instead of the hole-transporting layer HTL3. Further, the organic EL element OLED of the pixel PX3 includes the hole-transporting layer HTL3 instead of the charge-escape layer CEL.

As above, in the structure shown in FIG. 22, the pixel PX2 can include the charge-escape layer CEL instead of the hole-transporting layer HTL3, and the pixel PX3 can include the hole-transporting layer HTL3 instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 23.

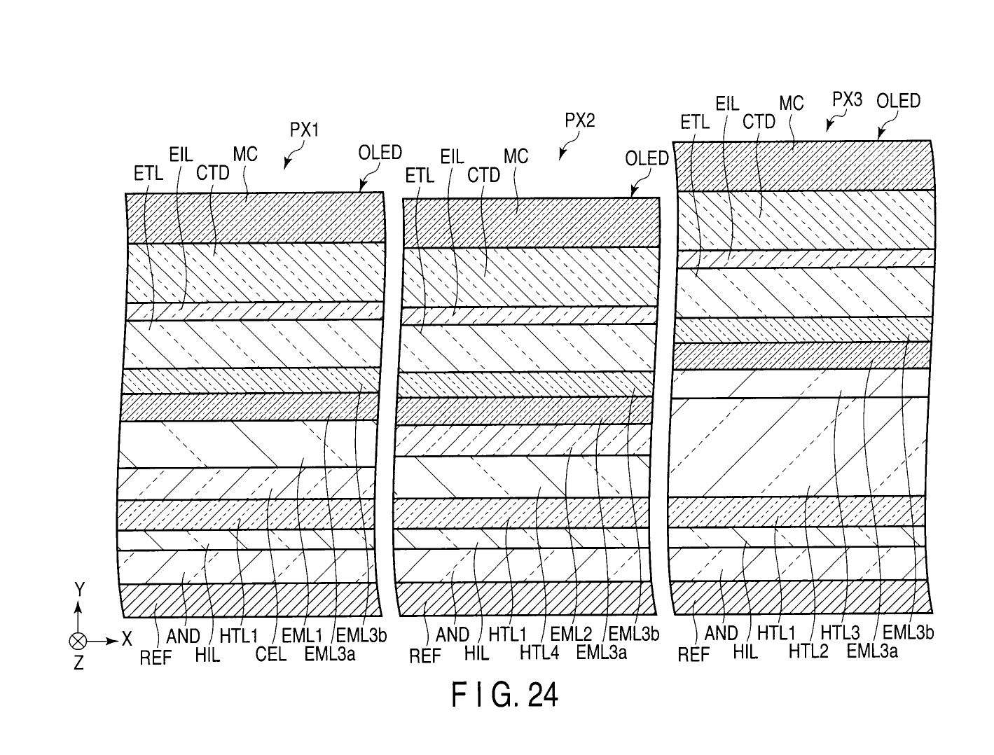

FIG. 24 is a sectional views schematically showing an organic EL device according to another modification. FIG. 24 shows the display panel DP from which some of the components are omitted.

The structure shown in FIG. 24 is the same as that described with reference to FIG. 22 except for the following.

In the structure shown in FIG. 24, the organic EL element OLED of the pixel PX1 includes the charge-escape layer CEL instead of the hole-transporting layer HTL4. Further, the organic EL element OLED of the pixel PX2 includes the hole-transporting layer HTL4 instead of the hole-transporting layer HTL3. In addition, the organic EL element OLED of the pixel PX3 includes the hole-transporting layer HTL3 instead of the charge-escape layer CEL.

As above, in the structure shown in FIG. 22, the pixel PX1 can include the charge-escape layer CEL instead of the hole-transporting layer HTL4, the pixel PX2 can include the hole-transporting layer HTL4 instead of the hole-transporting layer HTL3, and the organic EL element OLED of the pixel PX3 includes the hole-transporting layer HTL3 instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 24.

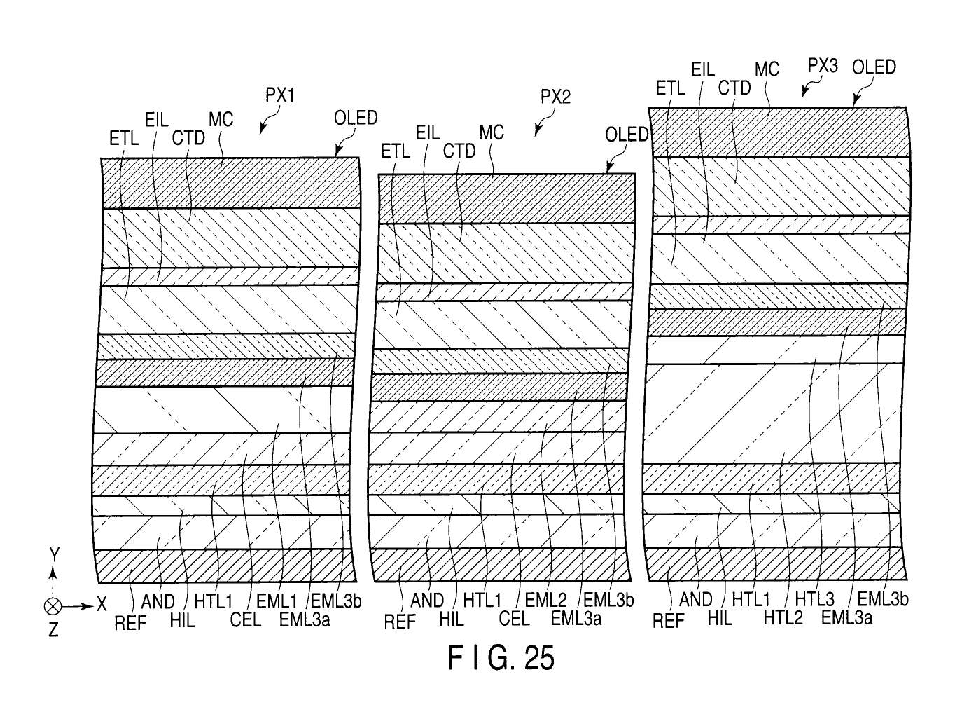

FIG. 25 is a sectional views schematically showing an organic EL device according to another modification. FIG. 25 shows the display panel DP from which some of the components are omitted.

The structure shown in FIG. 25 is the same as that described with reference to FIG. 24 except that the organic EL element OLED of the pixel PX2 includes the charge-escape layer CEL instead of the hole-transporting layer HTL4.

As above, in the structure shown in FIG. 24, the pixel PX2 can include the charge-escape layer CEL instead of the hole-transporting layer HTL4. Therefore, carrier balances in the emitting layers EML1 to EML3 and the optical thicknesses of the structures in which optical resonance should be caused can be adjusted by changing the multilayer structures, for example, as described with reference to FIG. 25.

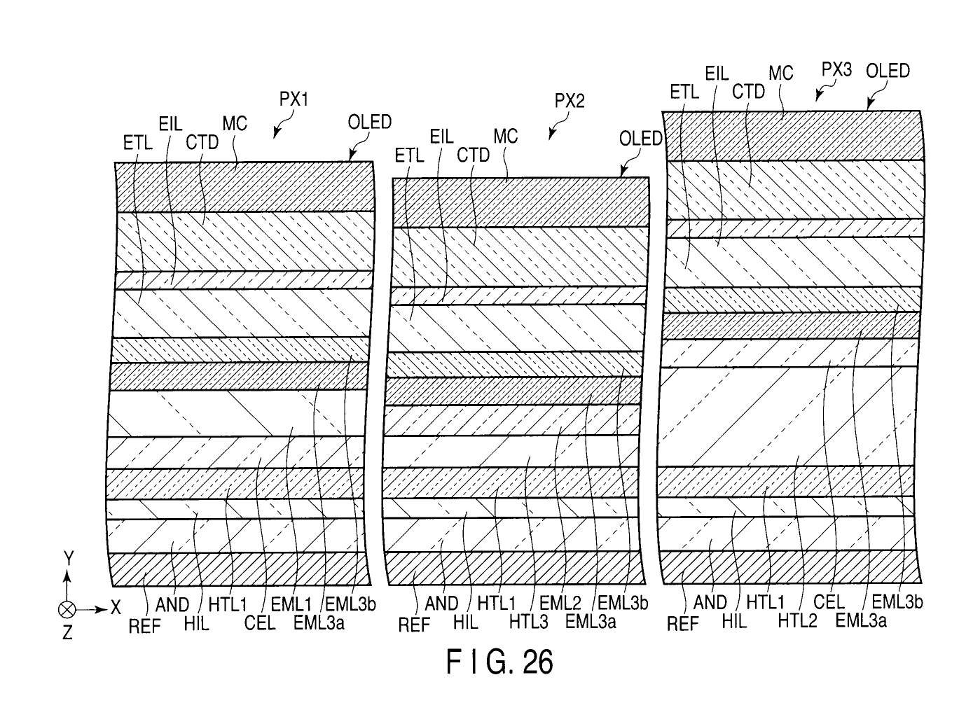

FIG. 26 is a sectional views schematically showing an organic EL device according to another modification. FIG. 26 shows the display panel DP from which some of the components are omitted.

The structure shown in FIG. 26 is the same as that described with reference to FIG. 24 except that the organic EL element OLED of the pixel PX2 includes the hole-transporting layer HTL3 instead of the hole-transporting layer HTL4, and the organic EL element OLED of the pixel PX3 includes the charge-escape layer CEL instead of the hole-transporting layer HTL3.

As above, in the structure shown in FIG. 24, the pixel PX2 can include the hole-transporting layer HTL3 instead of the hole-transporting layer HTL4, and the pixel PX3 can include the charge-escape layer CEL instead of the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 26.

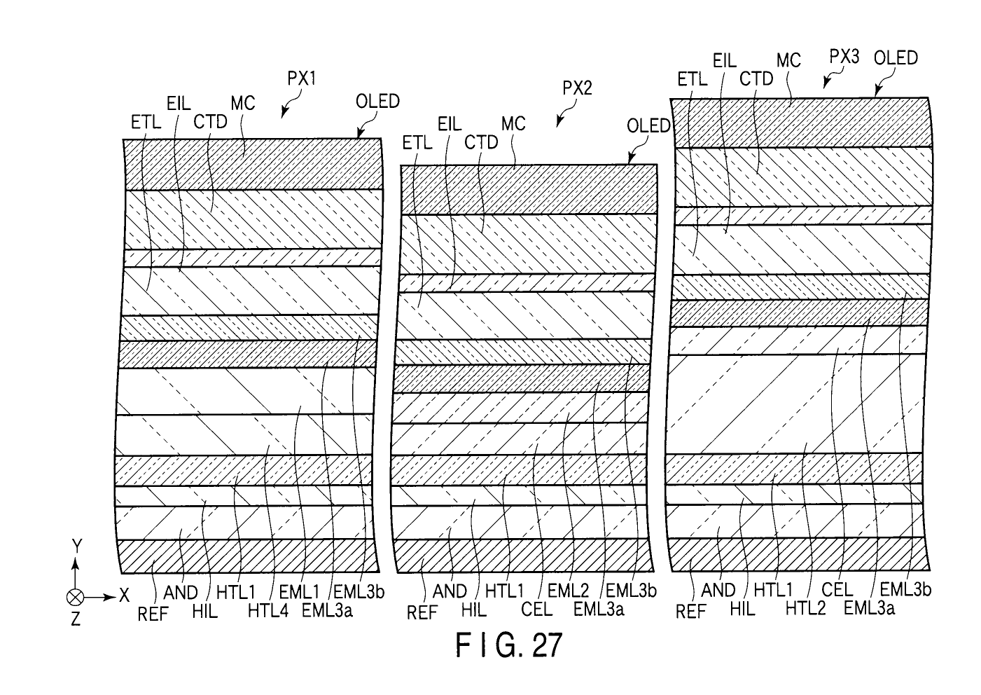

FIG. 27 is a sectional views schematically showing an organic EL device according to another modification. FIG. 27 shows the display panel DP from which some of the components are omitted.

The structure shown in FIG. 27 is the same as that described with reference to FIG. 26 except that the organic EL element OLED of the pixel PX1 includes the hole-transporting layer HTL4 instead of the charge-escape layer CEL, and the organic EL element OLED of the pixel PX2 includes the charge-escape layer CEL instead of the hole-transporting layer HTL3.

As above, in the structure shown in FIG. 26, the pixel PX1 can include the hole-transporting layer HTL4 instead of the charge-escape layer CEL, and the pixel PX2 can include the charge-escape layer CEL instead of the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 27.

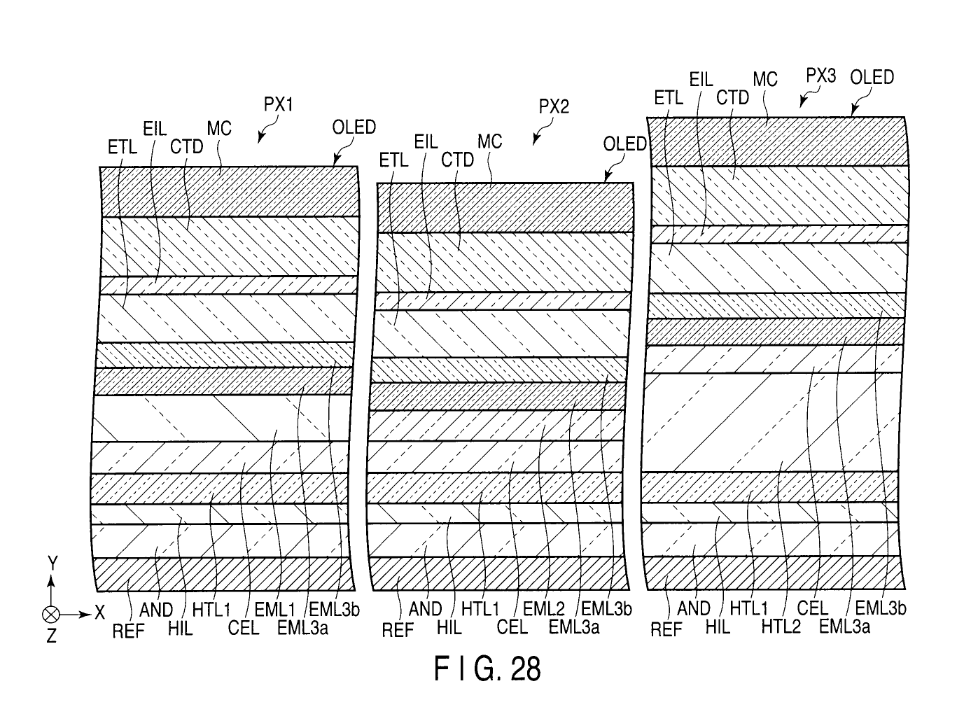

FIG. 28 is a sectional views schematically showing an organic EL device according to another modification. FIG. 28 shows the display panel DP from which some of the components are omitted.

The structure shown in FIG. 28 is the same as that described with reference to FIG. 26 except that the organic EL element OLED of the pixel PX2 includes the charge-escape layer CEL instead of the hole-transporting layer HTL3.

As above, in the structure shown in FIG. 26, the pixel PX2 can include the charge-escape layer CEL instead of the hole-transporting layer HTL3. Therefore, carrier balances in the emitting layers EML1 to EML3 and the optical thicknesses of the structures in which optical resonance should be caused can be adjusted by changing the multilayer structures, for example, as described with reference to FIG. 28.

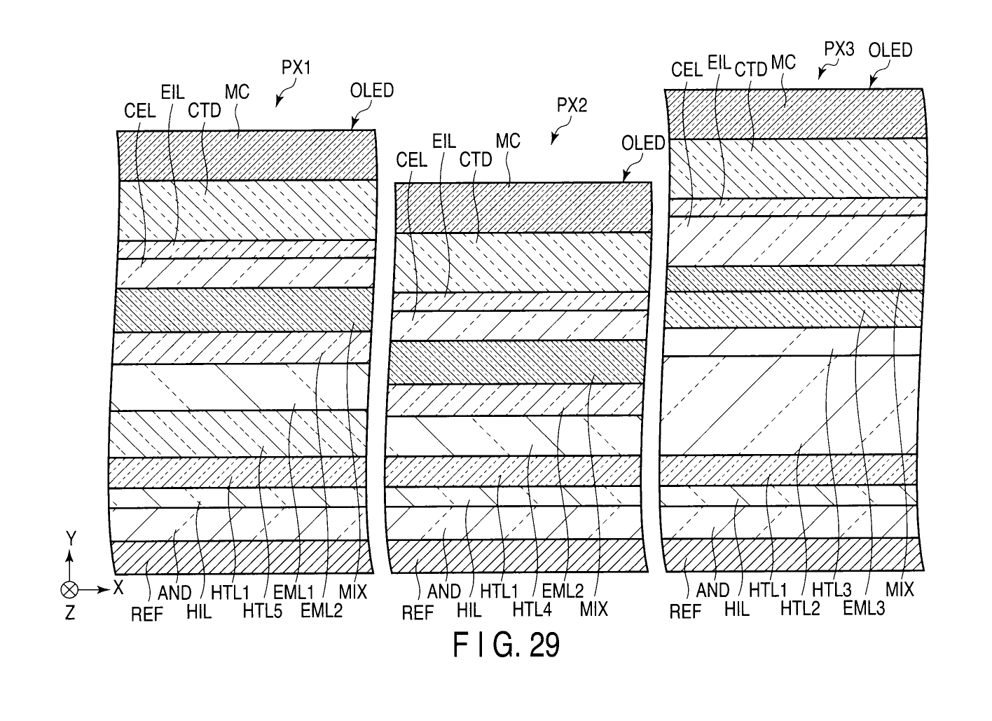

FIG. 29 is a sectional views schematically showing an organic EL device according to another modification. FIG. 29 shows the display panel DP from which some of the components are omitted.

The structure shown in FIG. 29 is the same as that described with reference to FIG. 20 except for the following.

In the structure shown in FIG. 29, the organic EL element OLED of the pixel PX1 includes the emitting layer EML2 instead of the emitting layers EML3a and EML3b, the organic EL element OLED of the pixel PX2 does not include the emitting layers EML3a and EML3b, and the organic EL element OLED of the pixel PX3 includes the emitting layer EML3 instead of the emitting layers EML3a and EML3b.

Further, in the structure shown in FIG. 29, each organic EL element OLED of the pixels PX1 to PX3 further includes an interface-mixing layer MIX. The interface-mixing layer is interposed between the emitting layer EML2 and the charge-escape layer CEL in the pixels PX1 and PX2 and is interposed between the emitting layer EML3 and the charge-escape layer CEL in the pixel PX3.

The interface-mixing layer MIX is an emitting layer having an electron-transporting property. The interface-mixing layer MIX includes a material used in the electron-transporting layer and at least one of the host material and the dopant used in the emitting layer. The interface-mixing layer emits, for example, blue light. Typically, the electron affinity of the interface-mixing layer MIX is between the electron affinity of the charge-escape layer CEL and the electron affinity of each of the emitting layers EML1 to EML3.

As above, in the structure shown in FIG. 20, the pixel PX1 can include the emitting layer EML2 instead of the emitting layers EML3a and EML3b, the emitting layers EML3a and EML3b of the pixel PX2 can be omitted, and the pixel PX3 can include the emitting layer EML3 instead of the emitting layers EML3a and EML3b. Therefore, carrier balances in the emitting layers EML1 to EML3 and the optical thicknesses of the structures in which optical resonance should be caused can be adjusted by changing the multilayer structures, for example, as described with reference to FIG. 29.

Further, in the case of providing the interface-mixing layer MIX as shown in FIG. 29, injection of electrons from the charge-escape layer CEL into the emitting layers EML1 to EML3 is enhanced. Therefore, the drive voltage can be lowered.

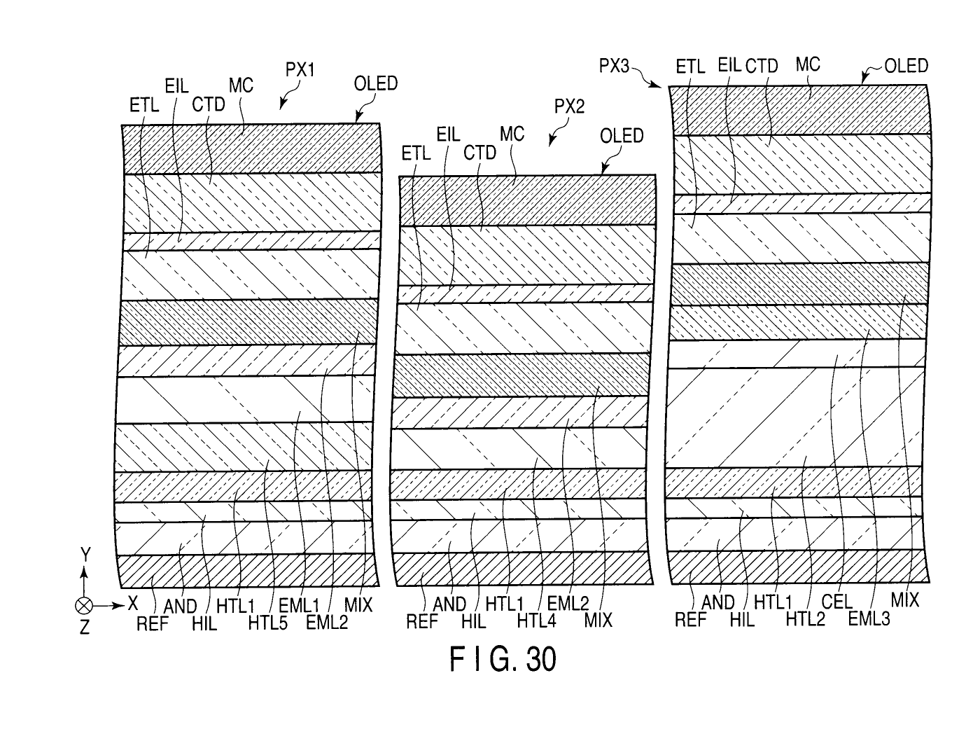

FIG. 30 is a sectional views schematically showing an organic EL device according to another modification. FIG. 30 shows the display panel DP from which some of the components are omitted.

The structure shown in FIG. 30 is the same as that described with reference to FIG. 12 except for the following.

In the structure shown in FIG. 30, the organic EL element OLED of the pixel PX1 includes the emitting layer EML2 instead of the emitting layer EML3, and the organic EL element OLED of the pixel PX2 does not include the emitting layer EML3.

Further, in the structure shown in FIG. 30, each organic EL element OLED of the pixels PX1 to PX3 further includes the interface-mixing layer MIX. The interface-mixing layer is interposed between the emitting layer EML2 and the electron-transporting layer ETL in the pixels PX1 and PX2 and is interposed between the emitting layer EML3 and the electron-transporting layer ETL in the pixel PX3. Here, the electron affinity of the interface-mixing layer MIX is typically between the electron affinity of the electron-transporting layer HTL and the electron affinity of each of the emitting layers EML1 to EML3.

As above, in the structure shown in FIG. 12, the pixel PX1 can include the emitting layer EML3 can be omitted from the pixel PX2. Therefore, carrier balances in the emitting layers EML1 to EML3 and the optical thicknesses of the structures in which optical resonance should be caused can be adjusted by changing the multilayer structures, for example, as described with reference to FIG. 30.

Further, in the case of providing the interface-mixing layer MIX as shown in FIG. 30, injection of electrons from the charge-escape layer CEL into the emitting layers EML1 to EML3 is enhanced. Therefore, the drive voltage can be lowered.

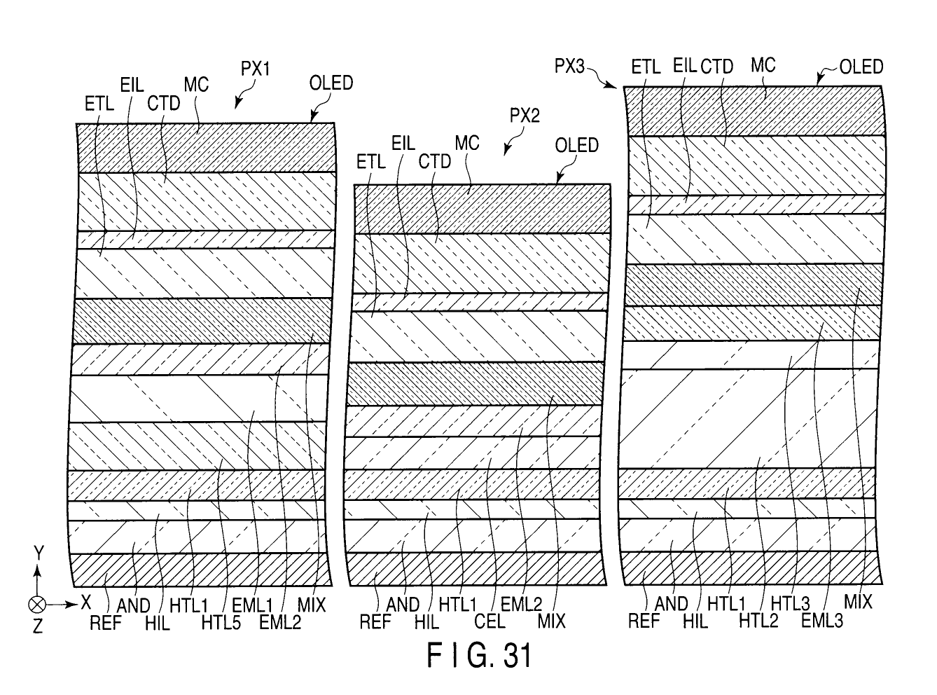

FIG. 31 is a sectional views schematically showing an organic EL device according to another modification. FIG. 31 shows the display panel DP from which some of the components are omitted.

The structure shown in FIG. 31 is the same as that described with reference to FIG. 30 except that the organic EL element OLED of the pixel PX2 includes the charge-escape layer CEL instead of the hole-transporting layer HTL4 and the organic EL element OLED of the pixel PX3 includes the hole-transporting layer HTL3 instead of the charge-escape layer CEL.

As above, in the structure shown in FIG. 30, the pixel PX2 can include the charge-escape layer CEL instead of the hole-transporting layer HTL4 and the pixel PX3 can include the hole-transporting layer HTL3 instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 31.

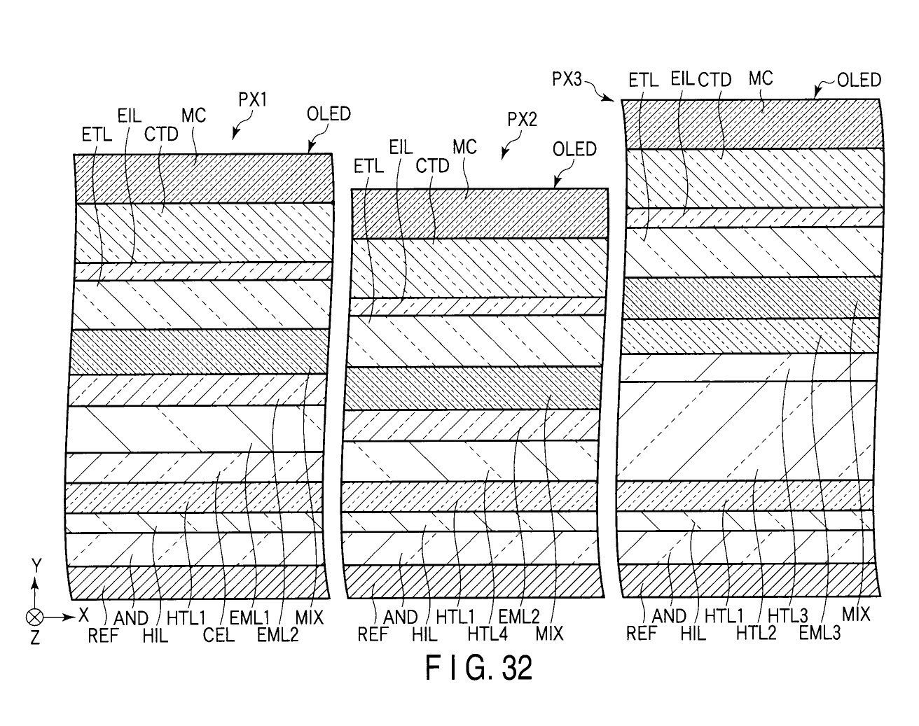

FIG. 32 is a sectional views schematically showing an organic EL device according to another modification. FIG. 32 shows the display panel DP from which some of the components are omitted.

The structure shown in FIG. 32 is the same as that described with reference to FIG. 30 except that the organic EL element OLED of the pixel PX1 includes the charge-escape layer CEL instead of the hole-transporting layer HTL5 and the organic EL element OLED of the pixel PX3 includes the hole-transporting layer HTL3 instead of the charge-escape layer CEL.

As above, in the structure shown in FIG. 30, the pixel PX1 can include the charge-escape layer CEL instead of the hole-transporting layer HTL5 and the pixel PX3 can include the hole-transporting layer HTL3 instead of the charge-escape layer CEL. Therefore, carrier balances in the emitting layers EML1 to EML3 and the optical thicknesses of the structures in which optical resonance should be caused can be adjusted by changing the multilayer structures, for example, as described with reference to FIG. 32.

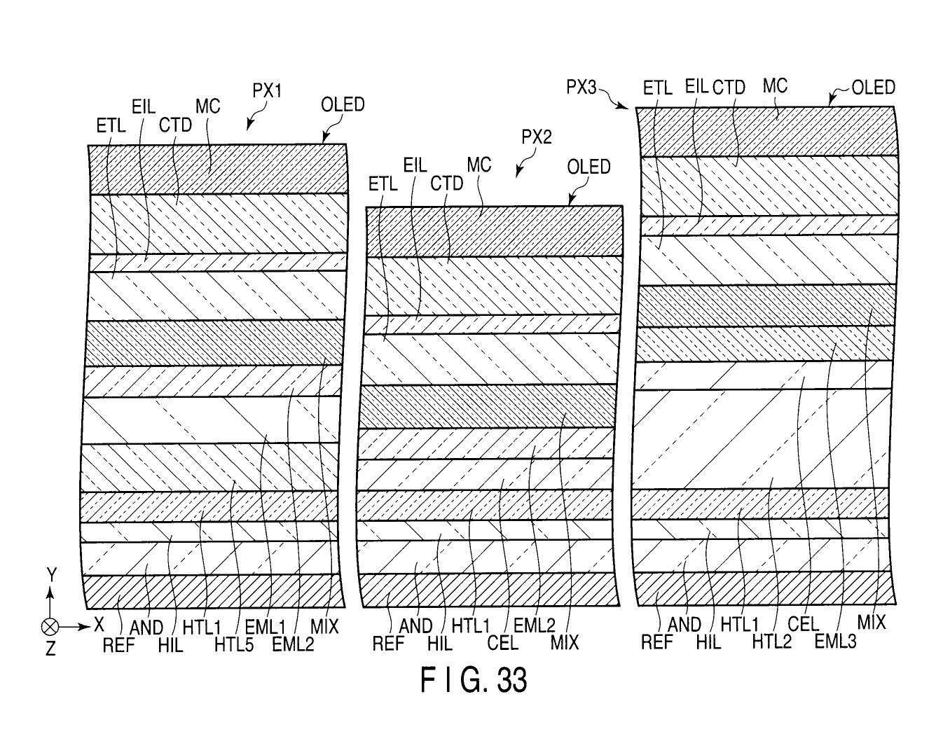

FIG. 33 is a sectional views schematically showing an organic EL device according to another modification. FIG. 33 shows the display panel DP from which some of the components are omitted.

The structure shown in FIG. 33 is the same as that described with reference to FIG. 30 except that the organic EL element OLED of the pixel PX2 includes the charge-escape layer CEL instead of the hole-transporting layer HTL4.

As above, in the structure shown in FIG. 30, the pixel PX2 can include the charge-escape layer CEL instead of the hole-transporting layer HTL4. Therefore, carrier balances in the emitting layers EML1 to EML3 and the optical thicknesses of the structures in which optical resonance should be caused can be adjusted by changing the multilayer structures, for example, as described with reference to FIG. 33.

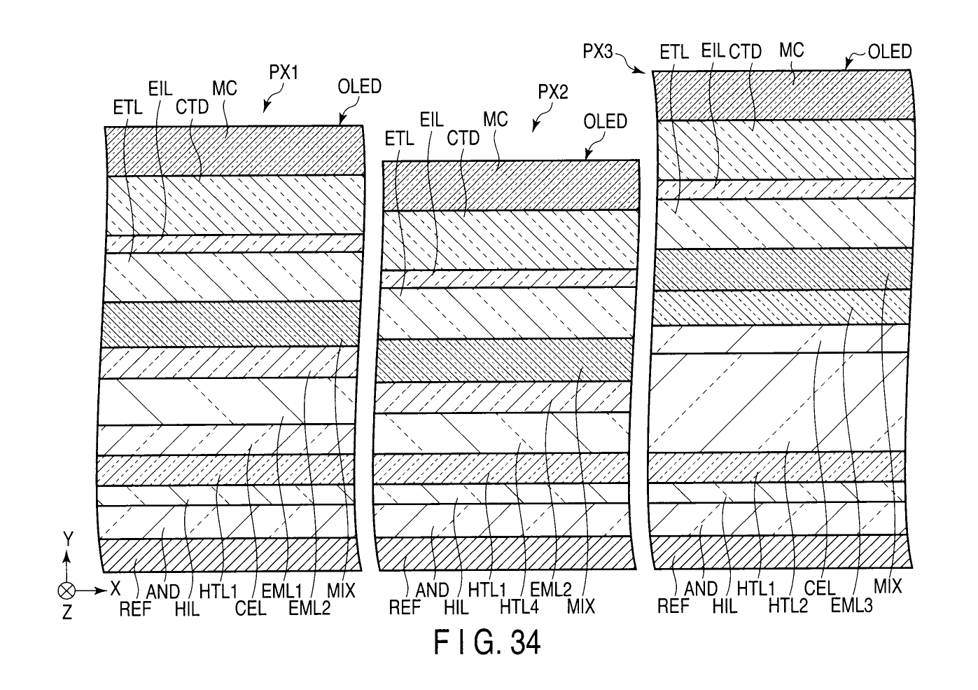

FIG. 34 is a sectional views schematically showing an organic EL device according to another modification. FIG. 34 shows the display panel DP from which some of the components are omitted.

The structure shown in FIG. 34 is the same as that described with reference to FIG. 30 except that the organic EL element OLED of the pixel PX1 includes the charge-escape layer CEL instead of the hole-transporting layer HTL5.

As above, in the structure shown in FIG. 30, the pixel PX1 can include the charge-escape layer CEL instead of the hole-transporting layer HTL5. Therefore, carrier balances in the emitting layers EML1 to EML3 and the optical thicknesses of the structures in which optical resonance should be caused can be adjusted by changing the multilayer structures, for example, as described with reference to FIG. 34.

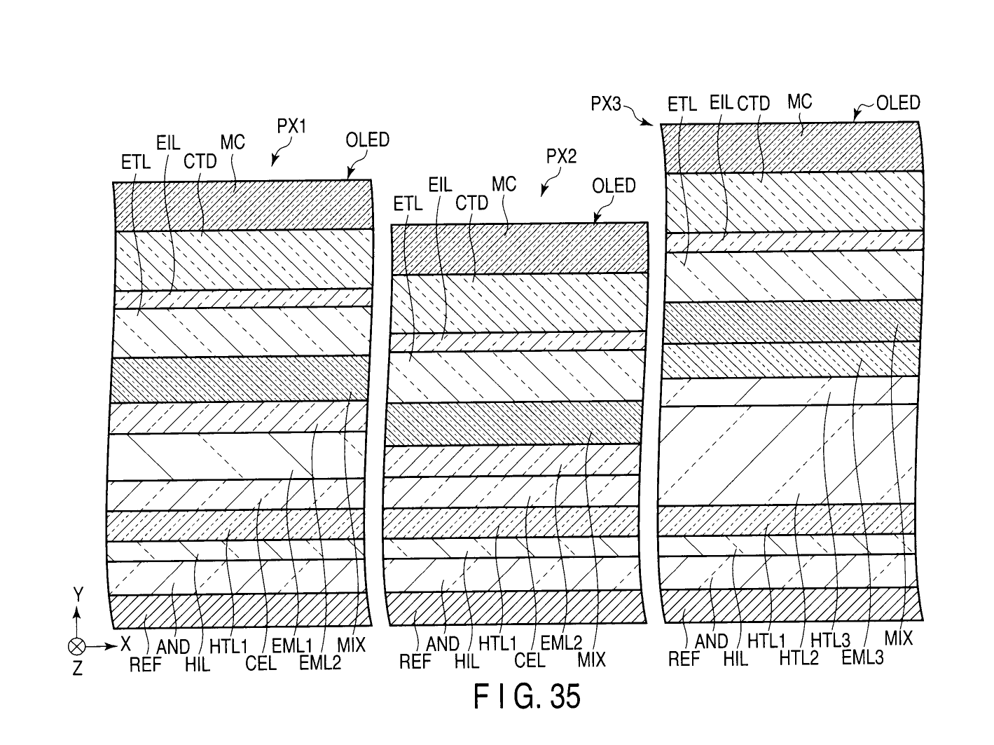

FIG. 35 is a sectional views schematically showing an organic EL device according to another modification. FIG. 35 shows the display panel DP from which some of the components are omitted.

The structure shown in FIG. 35 is the same as that described with reference to FIG. 31 except that the organic EL element OLED of the pixel PX1 includes the charge-escape layer CEL instead of the hole-transporting layer HTL5.

As above, in the structure shown in FIG. 31, the pixel PX1 can include the charge-escape layer CEL instead of the hole-transporting layer HTL5. Therefore, carrier balances in the emitting layers EML1 to EML3 and the optical thicknesses of the structures in which optical resonance should be caused can be adjusted by changing the multilayer structures, for example, as described with reference to FIG. 35.

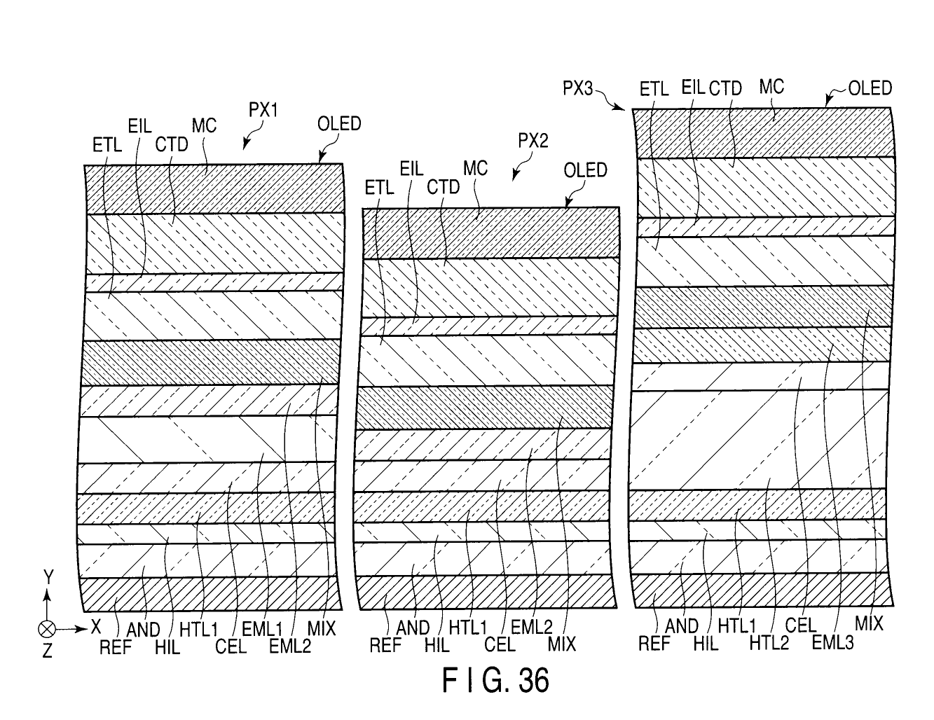

FIG. 36 is a sectional views schematically showing an organic EL device according to another modification. FIG. 36 shows the display panel DP from which some of the components are omitted.

The structure shown in FIG. 36 is the same as that described with reference to FIG. 33 except that the organic EL element OLED of the pixel PX1 includes the charge-escape layer CEL instead of the hole-transporting layer HTL5.

As above, in the structure shown in FIG. 33, the pixel PX1 can include the charge-escape layer CEL instead of the hole-transporting layer HTL5. Therefore, carrier balances in the emitting layers EML1 to EML3 and the optical thicknesses of the structures in which optical resonance should be caused can be adjusted by changing the multilayer structures, for example, as described with reference to FIG. 35.

Examples will be described below.

<Manufacture of Element A>

In this example, the organic EL element OLED shown in FIG. 3 was manufactured such that ionization energies and electron affinities of the layers or materials of this element satisfied the relationship shown in FIG. 4.

Specifically, the anode AND was formed by sputtering on a glass substrate. Here, indium tin oxide (ITO) was used as the material of the anode AND.

Then, using vacuum evaporation, the hole injection layer HIL, the hole-transporting layer HTL, the emitting layer EML, the charge-escape layer CEL, the electron-transporting layer ETL, the electron injection layer EIL and the cathode CTD were formed in this order on the anode AND.

A CuPc layer having a thickness of 10 nm was formed as the hole injection layer HIL. An α-NPD layer having a thickness of 50 nm was formed as the hole-transporting layer HTL. As the charged-escape layer CEL, formed was a layer having a thickness of 10 nm and including HMTPD as the second host material and 5 W % by mass of HTP as the second dopant. As the emitting layer, formed was a layer including ADN as the first host material and 1% by weight of BDAVBi, having a thickness of 30 nm, and emitting blue light as fluorescence. An Alq₃ layer having a thickness of 30 nm was formed as the electron-transporting layer ETL. An LiF layer having a thickness of 1 nm was formed as the electron injection layer EIL. An aluminum layer having a thickness of 100 nm was formed as the cathode.

An organic EL element was obtained by the above method. Hereinafter, the organic EL element thus obtained is referred to as “element A”.

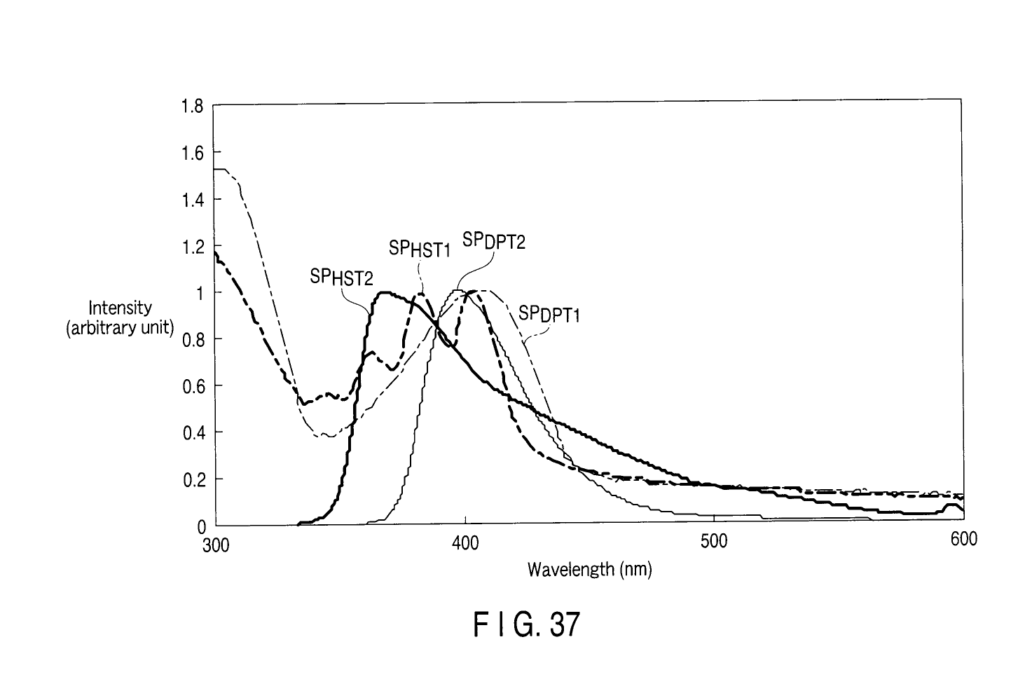

FIG. 37 shows absorption spectra of the first dopant and the first host material used in Example 1 and emission spectra of the second dopant and the second host material used in Example 1.

In FIG. 37, the curves SP_{HST1} and SP_{DPT1} indicate the absorption spectra of the first host material and the first dopant, respectively. On the other hand, the curves SP_{HST2} and SP_{DPT2} indicate the emission spectra of the second host material and the second dopant, respectively.

As will be apparent from FIG. 37, employed here was a design that allowed the light emitted by the charge-escape layer CEL to be utilized as excitation light for the emitting layer EML.

<Manufacture of Element B>

An organic EL element was manufactured by the same method as that described for the element A except that the second dopant in the charge-escape layer CEL was omitted. Hereinafter, the organic EL element thus obtained is referred to as “element B”.

<Evaluation>

Electric current was allowed to pass through each of the elements A and B so as to cause light emission. Then, the passage of electric current was stopped, and change of emission intensity with respect to elapsed time was monitored.

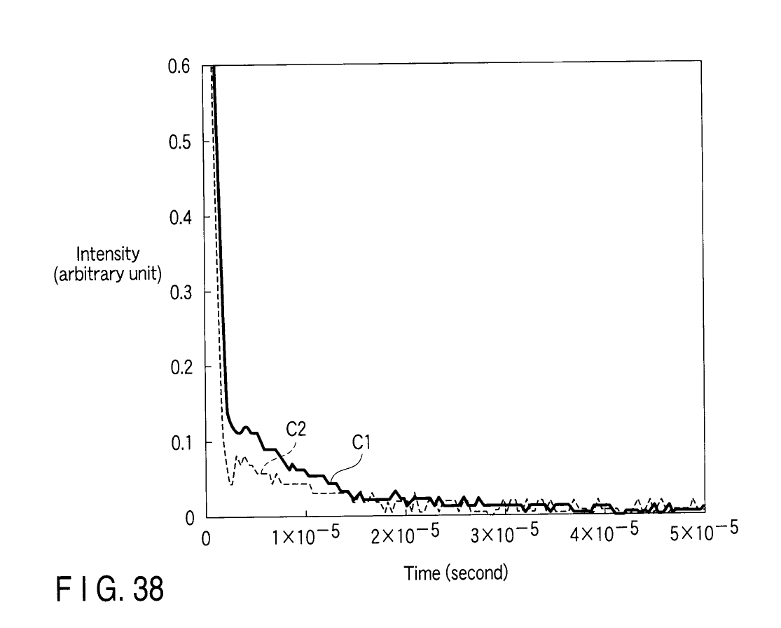

FIG. 38 is a graph showing transient responses obtained for the elements A and B. In FIG. 38, the curves C1 and C2 are response curves obtained for the elements A and B, respectively.

FIG. 38 reveals that contribution of singlet excitons generated by triplet-triplet annihilation to light emission is greater in the element A than that in the element B.

Next, the response curves A and B shown in FIG. 38 were analyzed. Specifically, the transient responses were analyzed to calculate the contribution of the singlet excitons directly generated by injection of charges into the element to light emission and the contribution of singlet excitons generated by triplet-triplet annihilation to light emission. The results are summarized in TABLE 1 below.

TABLE 1

| | | Theoretical | Element | Element |
|---|---|---|---|---|
| | | limit | A | B |
| Inner quantum | | 40 | 30.80 | 25.17 |
| efficiency (%) | | | | |
| Contribution | Direct | 25 | 20.00 | 22.51 |
| of excintons | emission | | | |
| to light | TTF | 15 | 10.80 | 2.66 |
| emission (%) | emission | | | |

In TABLE 1, “Inner quantum efficiency” indicates a ratio of the number of excitons utilized for light emission with respect to the total number of excitons directly generated by injection of charges into the organic EL element. In TABLE 1, “Direct emission” indicates light emission caused by singlet excitons directly generated by injection of charges into the organic EL element, and “TTF emission” indicates light emission caused by singlet excitons generated by triplet-triplet annihilation.

As shown in TABLE 1, the intensity of emission that the singlet excitons generated by triplet-triplet annihilation caused was much higher in the element A than that in the element B. In addition, the element A achieved an inner quantum efficiency much higher than that achieved by the element B.

Note that the intensity of emission that the singlet excitons directly generated by injection of charges into the element was slightly lower in the element A than that in element B. The reason for this is assumed to be a slight deterioration of carrier balance in the emitting layer EML.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic electroluminescence device comprising:
an anode;
a cathode;
an emitting layer positioned between the anode and the cathode and including a first host material and a first dopant, the first host material having a hole-transporting property, the first dopant having a blue-fluorescent property, fluorescent of the first dopant exhibiting the maximum intensity at a first wavelength; and
an organic layer in contact with the emitting layer between the cathode and the emitting layer and including a second host material and a second dopant, the second host material having an electron-transporting property, the second dopant having at least one of fluorescent and phosphorescent properties, the second host material having an ionization energy higher than an ionization energy of the first host material, the second dopant having an ionization energy lower than the ionization energy of the first host material, luminescence of the second dopant exhibiting the maximum intensity at a second wavelength shorter than the first wavelength.

2. The device according to claim 1, wherein an electron affinity of the second host material is lower than an electron affinity of the first host material.

3. The device according to claim 1, wherein the second dopant emits a visible or ultraviolet ray.

4. An organic electroluminescence device comprising:
first to third anodes;
a cathode facing the first to third anodes;
a first emitting layer positioned between the first anode and the cathode and including a host material and a dopant having a red-fluorescent property;
a second emitting layer positioned between the second anode and the cathode and the cathode and including a host material and a dopant having a green-fluorescent property;
a third emitting layer positioned between the third anode and the cathode and including a first host material having a hole-transporting property and a first dopant having a blue-fluorescent property, fluorescent of the first dopant exhibiting the maximum intensity at a first wavelength; and
an organic layer in contact with the third emitting layer between the cathode and the third emitting layer and including a second host material having an electron-transporting property and a second dopant having at least one of fluorescent and phosphorescent properties, the second host material having an ionization energy higher than an ionization energy of the first host material, the second dopant having an ionization energy lower than the ionization energy of the first host material, luminescence of the second dopant exhibiting the maximum intensity at a second wavelength shorter than the first wavelength.

5. The device according to claim 4, wherein the first emitting layer extends over the first anode, the second emitting layer extends over the first and second anodes, portions of the second emitting layer above the first anode being positioned between the first emitting layer and the cathode, and the third emitting layer extends over the first to third anodes, portions of the third emitting layer above the first and second anodes being positioned between the second emitting layer and the cathode.

6. The device according to claim 4, wherein the first emitting layer extends over the first anode, the second emitting layer extends over the second anode, and the third emitting layer extends over the first and third anodes, a portion of the third emitting layer above the first anode being positioned between the first emitting layer and the cathode.

7. The device according to claim 4, wherein the first emitting layer extends over the first anode, the second emitting layer extends over the second anode, and the third emitting layer extends over the first to third anodes, a portion of the third emitting layer above the first anode being positioned between the first emitting layer and the cathode, a portion of the third emitting layer above the second anode being positioned between the second emitting layer and the cathode.

8. The device according to claim 4, wherein the first emitting layer extends over the first anode, the second emitting layer extends over the first and second anodes, a portion of the second emitting layer above the first anode being positioned between the first emitting layer and the cathode, and the third emitting layer extends over the third anode.

9. The device according to claim 4, wherein the first emitting layer extends over the first anode, the second emitting layer extends over the second anode, the third emitting layer extends over the first to third anodes, a portion of the third emitting layer above the first anode being positioned between the first emitting layer and the cathode, a portion of the third emitting layer above the second anode being positioned between the second emitting layer and the cathode, and the third emitting layer including first and second layers, the second layer being positioned between the first layer and the cathode.

10. The device according to claim 9, wherein a hole mobility in the second layer is lower than a hole mobility in the first layer or a level of the highest occupied molecular orbital in the second layer is higher than a level of the highest occupied molecular orbital in the first layer.

11. An organic electroluminescence device comprising:
an anode;
a cathode;
an emitting layer positioned between the anode and the cathode and including a first host material and a first dopant, the first host material having an electron-transporting property, the first dopant having a blue-fluorescent property, fluorescent of the first dopant exhibiting the maximum intensity at a first wavelength; and
an organic layer in contact with the emitting layer between the anode and the emitting layer and including a second host material and a second dopant, the second host material having a hole-transporting property, the second dopant having at least one of fluorescent and phosphorescent properties, the second host material having an electron affinity lower than an electron affinity energy of the first host material, the second dopant having an electron affinity higher than the electron affinity of the first host material, luminescence of the second dopant exhibiting the maximum intensity at a second wavelength shorter than the first wavelength.

12. The device according to claim 11, wherein an ionization energy of the second host material is lower than an ionization energy of the first host material.

13. The device according to claim 11, wherein the second dopant emits a visible or ultraviolet ray.

14. An organic electroluminescence device comprising:
first to third anodes;
a cathode facing the first to third anodes;
a first emitting layer positioned between the first anode and the cathode and including a host material and a dopant having a red-fluorescent property;
a second emitting layer positioned between the second anode and the cathode and the cathode and including a host material and a dopant having a green-fluorescent property;
a third emitting layer positioned between the third anode and the cathode and including a first host material having an electron-transporting property and a first dopant having a blue-fluorescent property, fluorescent of the first dopant exhibiting the maximum intensity at a first wavelength; and
an organic layer in contact with the third emitting layer between the third anode and the third emitting layer and including a second host material and a second dopant, the second host material having a hole-transporting property, the second dopant having at least one of fluorescent and phosphorescent properties, the second host material having an electron affinity lower than an electron affinity energy of the first host material, the second dopant having an electron affinity higher than the electron affinity of the first host material, luminescence of the second dopant exhibiting the maximum intensity at a second wavelength shorter than the first wavelength.

15. The device according to claim 14, wherein the first emitting layer extends over the first anode, the second emitting layer extends over the first and second anodes, portions of the second emitting layer above the first anode being positioned between the first emitting layer and the cathode, and the third emitting layer extends over the first to third anodes, portions of the third emitting layer above the first and second anodes being positioned between the second emitting layer and the cathode.

16. The device according to claim 14, wherein the first emitting layer extends over the first anode, the second emitting layer extends over the second anode, and the third emitting layer extends over the first and third anodes, a portion of the third emitting layer above the first anode being positioned between the first emitting layer and the cathode.

17. The device according to claim 14, wherein the first emitting layer extends over the first anode, the second emitting layer extends over the second anode, and the third emitting layer extends over the first to third anodes, a portion of the third emitting layer above the first anode being positioned between the first emitting layer and the cathode, a portion of the third emitting layer above the second anode being positioned between the second emitting layer and the cathode.

18. The device according to claim 14, wherein the first emitting layer extends over the first anode, the second emitting layer extends over the first and second anodes, a portion of the second emitting layer above the first anode being positioned between the first emitting layer and the cathode, and the third emitting layer extends over the third anode.

19. The device according to claim 14, wherein the first emitting layer extends over the first anode, the second emitting layer extends over the second anode, the third emitting layer extends over the first to third anodes, a portion of the third emitting layer above the first anode being positioned between the first emitting layer and the cathode, a portion of the third emitting layer above the second anode being positioned between the second emitting layer and the cathode, and the third emitting layer including first and second layers, the second layer being positioned between the first layer and the cathode.

20. The device according to claim 19, wherein a hole mobility in the second layer is lower than a hole mobility in the first layer or a level of the highest occupied molecular orbital in the second layer is higher than a level of the highest occupied molecular orbital in the first layer.
